(19) United States
(12) Patent Application Publication
(10) Pub. No.: US 2026/0144046 A1
(43) Pub. Date: May 21, 2026

(54) SEMICONDUCTOR DEVICE

(71) Applicant: Samsung Electronics Co., Ltd., Suwon-si (KR)

(72) Inventors: Gwanho KIM, Suwon-si (KR); Kyongbeom KOH, Suwon-si (KR); KI-IL KIM, Suwon-si (KR); HYUNGGOO LEE, Suwon-si (KR)

(21) Appl. No.: 19/291,199

(22) Filed: Aug. 5, 2025

(30) Foreign Application Priority Data
Nov. 15, 2024 (KR) 10-2024-0163494

(51) Int. Cl. H01L 23/528; H10D 30/00; H10D 64/23; H10D 64/27

(52) U.S. Cl. CPC H10W 20/43; H10D 30/501; H10D 64/254; H10D 64/518

(57) ABSTRACT

A semiconductor device includes a substrate, a lower power wire provided in a lower portion of the substrate, a rear surface active contact on the lower power wire, a rear surface separation pattern separating the rear surface active contact on the lower power wire, a channel pattern on the rear surface separation pattern, the channel pattern including a plurality of semiconductor patterns stacked spaced apart from each other, a source/drain pattern connected to the channel pattern, a gate electrode between the rear surface separation pattern and one of the plurality of semiconductor patterns, and a pillar protection pattern interposed between the gate electrode and the rear surface separation pattern. The pillar protection pattern and the rear surface separation pattern respectively include different insulating materials.

### CROSS-REFERENCE TO RELATED APPLICATION(S)

This U.S. non-provisional patent application claims priority under 35 U.S.C. § 119 to Korean Patent Application No. 10-2024-0163494, filed on Nov. 15, 2024 in the Korean Intellectual Property Office, the disclosure of which is hereby incorporated by reference in its entirety.

### BACKGROUND

The present disclosure herein relates to a semiconductor device, and more particularly, to a semiconductor device including a field effect transistor.

A semiconductor device includes an integrated circuit composed of metal-oxide-semiconductor field effect transistors (MOSFETs). As a size and a design rule of the semiconductor device are gradually decreasing, scaling down of the metal-oxide-semiconductor field effect transistors is also gradually being accelerated. As the metal-oxide-semiconductor field effect transistors are gradually scaled down, operation characteristics of the semiconductor device may be deteriorated. Accordingly, research on various methods for overcoming limitation caused by high-integration of the semiconductor device and forming the semiconductor device with more excellent performance is being conducted.

### SUMMARY

The present disclosure provides a semiconductor device with improved reliability and electrical characteristics.

A technical goal of the inventive concept is not limited to the goal mentioned above, and other technical goals that are not mentioned may be clearly understood from description below by those skilled in the art.

In an embodiment of the inventive concept, a semiconductor device includes a substrate, a lower power wire configured to be supplied a power voltage and provided in a lower portion of the substrate, a rear surface active contact on the lower power wire, a rear surface separation pattern separating the rear surface active contact on the lower power wire, a channel pattern on the rear surface separation pattern, the channel pattern including a plurality of semiconductor patterns stacked spaced apart from each other, a source/drain pattern connected to the channel pattern, a gate electrode between the rear surface separation pattern and one of the plurality of semiconductor patterns and between each of the plurality of semiconductor patterns, and a pillar protection pattern interposed between the gate electrode and the rear surface separation pattern. The pillar protection pattern and the rear surface separation pattern include different insulating materials respectively.

In an embodiment of the inventive concept, a semiconductor device includes a substrate including a rear surface separation pattern, a lower power wire configured to be supplied a power voltage and buried in a lower portion of the substrate, a channel pattern on the substrate, the channel pattern including a plurality of semiconductor patterns stacked spaced apart from each other, source/drain patterns connected to the channel pattern, a gate electrode between the substrate and one of the plurality of semiconductor patterns and between each of the plurality of semiconductor patterns, a rear surface active contact electrically connecting the lower power wire and one of the source/drain patterns, and including a body portion and a protrusion portion on the body portion, an upper active contact electrically connecting the other one of the source/drain patterns, and a pillar protection pattern interposed between the gate electrode and the rear surface separation pattern. The pillar protection pattern extends onto a lower surface of the other one of the source/drain patterns, and the pillar protection pattern is separated by the protrusion portion of the rear surface active contact.

In an embodiment of the inventive concept, a semiconductor device includes a substrate including a rear surface separation pattern, a device separation layer provided on the substrate to define the rear surface separation pattern, a channel pattern on the rear surface separation pattern, the channel pattern including a plurality of semiconductor patterns stacked spaced apart from each other, and the plurality of semiconductor patterns including a first semiconductor pattern, a second semiconductor pattern and a third semiconductor pattern, source/drain patterns connected to the channel pattern, a gate electrode between the plurality of semiconductor patterns, the gate electrode including a first inner electrode, a second inner electrode, and a third inner electrode interposed between adjacent semiconductor patterns among the plurality of semiconductor patterns, and an outer electrode on the third semiconductor pattern, a gate insulating layer interposed between the gate electrode and the channel pattern, a gate spacer on a sidewall of the gate electrode, a gate capping pattern on an upper surface of the gate electrode, an interlayered insulating layer covering the source/drain patterns and the gate capping pattern, an upper active contact penetrating the interlayered insulating layer to be electrically connected to a first source/drain pattern of the source/drain patterns, a metal-semiconductor compound layer interposed between the upper active contact and the first source/drain pattern, a gate contact penetrating the interlayered insulating layer and the gate capping pattern to be electrically connected to the gate electrode, a first metal layer on the interlayered insulating layer, the first metal layer including a first wire electrically connected to the gate contact, a second metal layer on the first metal layer, the second metal layer including a second wire electrically connected to the first metal layer, a lower power wire configured to be supplied a power voltage and provided in a lower portion of the substrate, a rear surface active contact penetrating the substrate to electrically connect the lower power wire to a second source/drain pattern of the source/drain patterns, and a pillar protection pattern interposed between the rear surface separation pattern and the gate insulating layer on the first inner electrode. The uppermost surface of the rear surface active contact is located at a higher level than an upper surface of the pillar protection pattern and an upper surface of the rear surface separation pattern. The pillar protection pattern and the rear surface separation pattern respectively include different insulating materials.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIGS. 1 to 3 are conceptual diagrams for describing logic cells of a semiconductor device according to embodiments of the inventive concept;

FIG. 4 is a plan view for describing a semiconductor device according to embodiments of the inventive concept;

FIGS. 5A to 5D are respectively cross-sectional views taken along line A-A′, line B-B′, line C-C′ and line D-D′ of FIG. 4 according to example embodiments;

FIG. 6 is an enlarged diagram illustrating region M of FIG. 5A according to example embodiments;

FIGS. 7A and 7B are cross-sectional views for describing a semiconductor device according to another embodiment; and

FIGS. 8A, 8B, 9A, 9B, 10A to 10C, 11A to 11C, 12A to 12C, 13A to 13D, 14A to 14D, 15A to 15D, 16A to 16D, 17A to 17D, 18A to 18D, 19A to 19D, and 20A to 20D are diagrams illustrating a method for manufacturing a semiconductor device according to embodiments of the inventive concept.

### DETAILED DESCRIPTION

Hereinafter, embodiments according to the inventive concept will be described in more detail with reference to the accompanying drawings in order to more specifically describe the inventive concept.

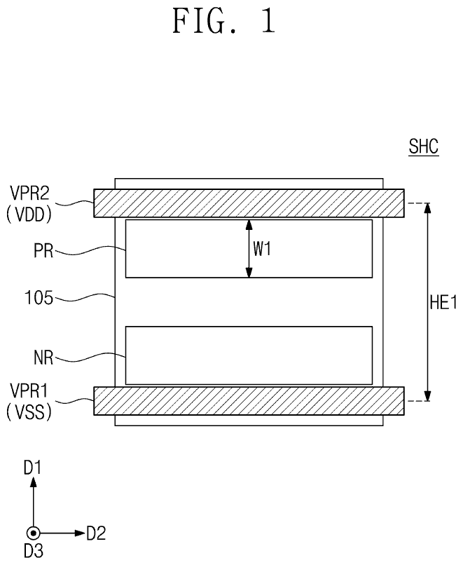

FIGS. 1 to 3 are conceptual diagrams for describing logic cells of a semiconductor device according to embodiments of the inventive concept.

Referring to FIG. 1, a single height cell SHC may be provided. Specifically, a first lower power wire VPR1 and a second lower power wire VPR2 may be provided on a lower portion of a substrate 105. The first lower power wire VPR1 may be a path through which a source voltage VSS, for example, a ground voltage is provided. The second lower power wire VPR2 may be a path through which a drain voltage VDD, for example, a power voltage is provided.

The single height cell SHC may be defined between the first lower power wire VPR1 and the second lower power wire VPR2. The single height cell SHC may include one P-type MOSFET (PMOSFET) region PR and one N-type MOSFET (NMOSFET) region NR. For example, the single height cell SHC may have a structure in which a complementary MOS (CMOS) is provided between the first lower power wire VPR1 and the second lower power wire VPR2.

The PMOSFET region PR and the NMOSFET region NR may each have a width in a first direction D1. A length of the single height cell SHC in the first direction D1 may be defined as a first height HE1. The first height HE1 may be substantially the same as a distance (for example, a pitch) between the first lower power wire VPR1 and the second lower power wire VPR2.

The single height cell SHC may constitute one logic cell. In the present specification, the logic cell may mean a logic device (for example, AND, OR, XOR, XNOR, an inverter, or the like) that performs a specific function. For example, the logic cell may include transistors for constituting the logic device, and wires connecting the transistors each other.

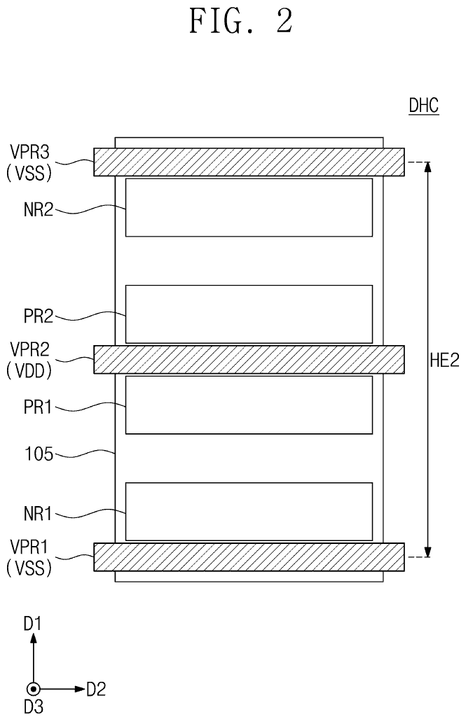

Referring to FIG. 2, a double height cell DHC may be provided. Specifically, the first lower power wire VPR1, the second lower power wire VPR2, and a third lower power wire VPR3 may be provided on the substrate 105. The second lower power wire VPR2 may be disposed between the first lower power wire VPR1 and the third lower power wire VPR3. The third lower power wire VPR3 may be a path through which the source voltage VSS is provided.

The double height cell DHC may be defined between the first lower power wire VPR1 and the third lower power wire VPR3. The double height cell DHC may include a first PMOSFET region PR1, a second PMOSFET region PR2, a first NMOSFET region NR1, and a second NMOSFET region NR2.

The first NMOSFET region NR1 may be adjacent to the first lower power wire VPR1. The second NMOSFET region NR2 may be adjacent to the third lower power wire VPR3. First and second PMOSFET regions PR1 and PR2 may be adjacent to the second lower power wire VPR2. On a plan view, the second lower power wire VPR2 may be disposed between the first and second PMOSFET regions PR1 and PR2.

A length of the double height cell DHC in the first direction D1 may be defined as a second height HE2. The second height HE2 may be about twice longer than the first height HE1 of FIG. 1. The first and second PMOSFET regions PR1 and PR2 of the double height cell DHC may operate together as one PMOSFET region. Accordingly, a channel size of a PMOS transistor of the double height cell DHC may be greater than a channel size of the PMOS transistor of the single height cell SHC of FIG. 1.

For example, the channel size of the PMOS transistor of the double height cell DHC may be about twice longer than the channel size of the PMOS transistor of the single height cell SHC. As a result, the double height cell DHC may operate faster than the single height cell SHC. According to the inventive concept, the double height cell DHC illustrated in FIG. 2 may be defined as a multi-height cell. Although not shown, the multi-height cell may include a triple height cell of which a cell height is about three times longer than that of the single height cell SHC.

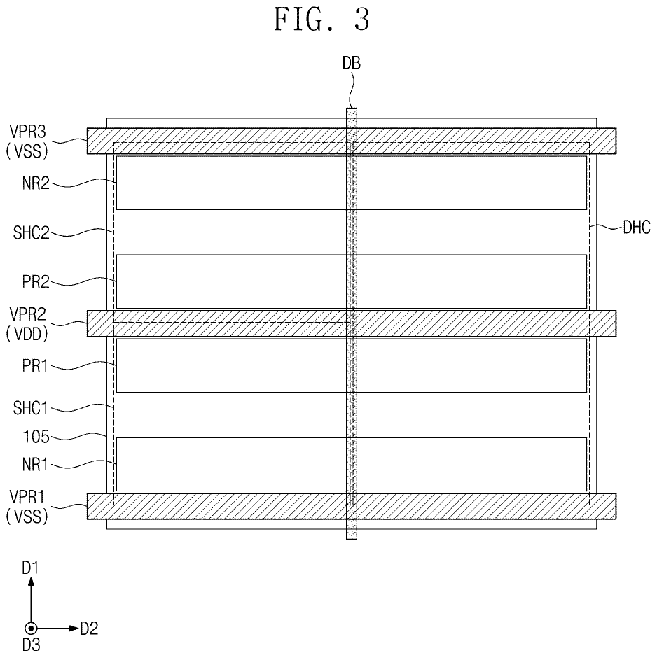

Referring to FIG. 3, a first single height cell SHC1, a second single height cell SHC2, and the double height cell DHC may be two-dimensionally disposed on the substrate 105. The first single height cell SHC1 may be disposed between the first and second lower power wires VPR1 and VPR2. The second single height cell SHC2 may be disposed between the second and third lower power wires VPR2 and VPR3. The second single height cell SHC2 may be adjacent to the first single height cell SHC1 in the first direction D1.

The double height cell DHC may be disposed between the first and third lower power wires VPR1 and VPR3. The double height cell DHC may be adjacent to the first and second single height cells SHC1 and SHC2 in a second direction D2. Here, the first direction D1 may intersect the second direction D2. The first direction D1 and the second direction D2 may represent directions in parallel with an upper surface of the substrate 105, and the first direction D1 and the second direction D2 may include directions perpendicular to each other. A third direction D3 may be a thickness direction of the substrate 105. The third direction D3 may represent a direction perpendicular to the upper surface of the substrate 105. For example, the third direction D3 may be a direction vertical to the upper surface of the substrate 105.

A separation structure DB may be provided between the first single height cell SHC1 and the double height cell DHC, and between the second single height cell SHC2 and the double height cell DHC. An active region of the double height cell DHC may be electrically separated from an active region of each of the first and second single height cells SHC1 and SHC2 by the separation structure DB.

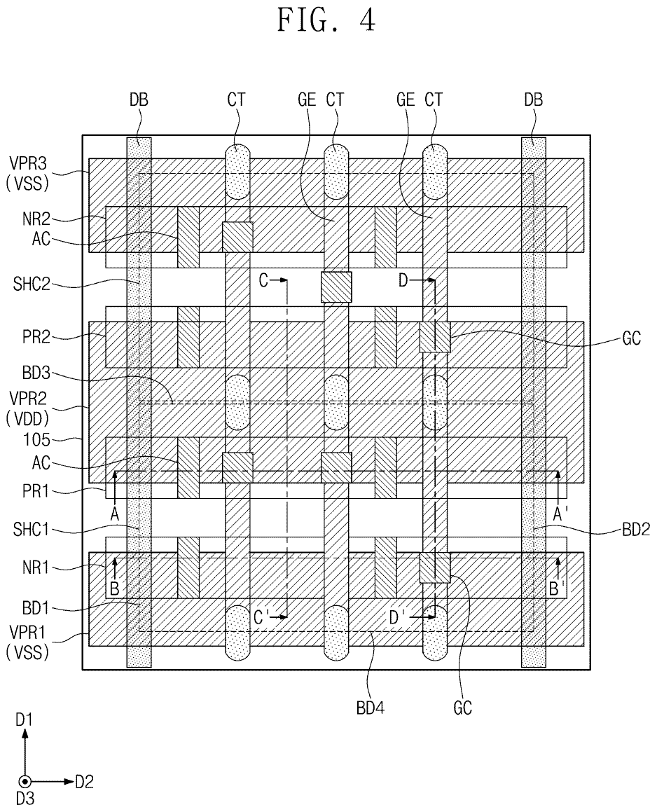

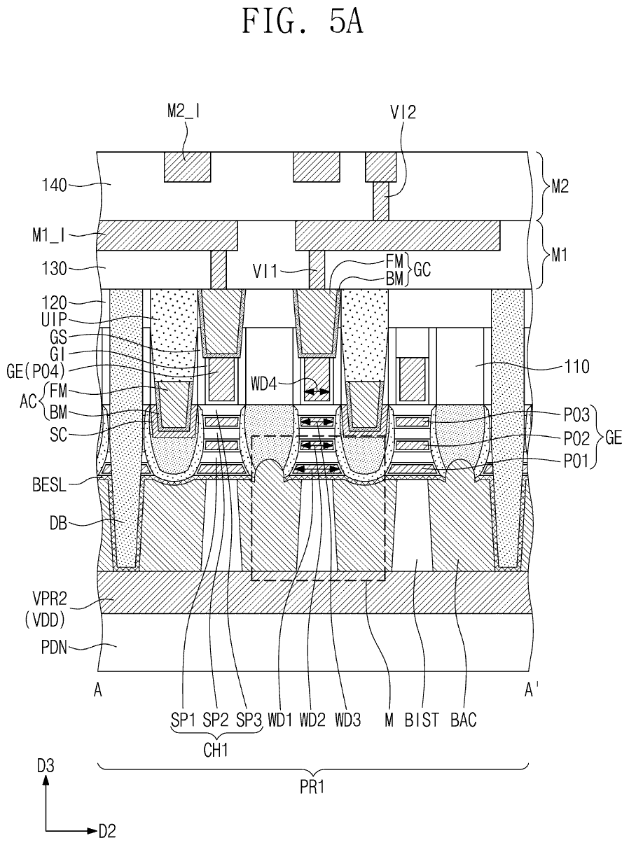

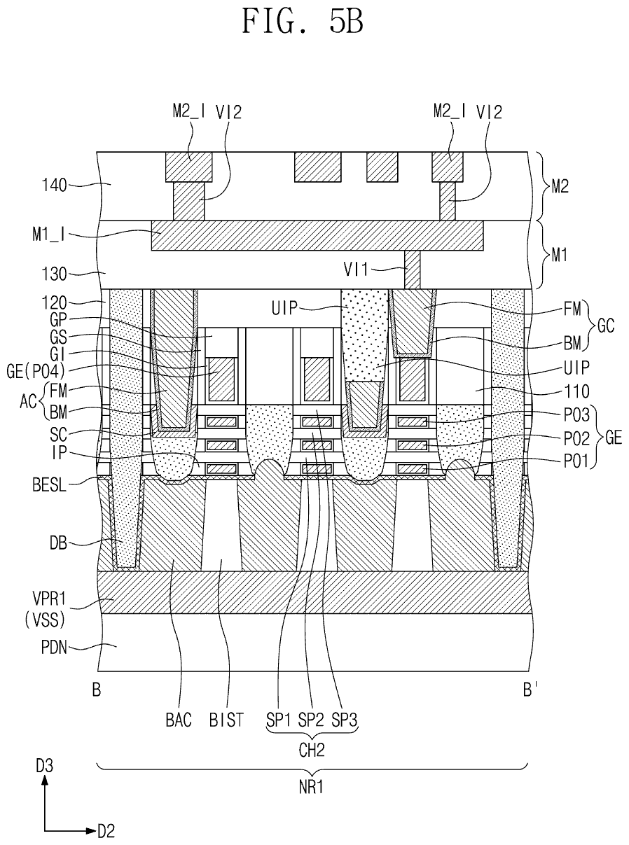

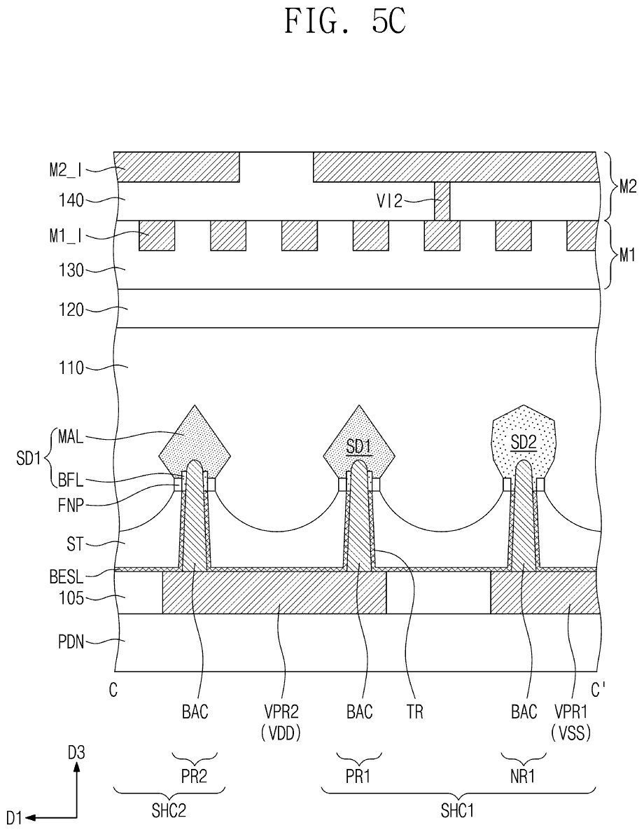

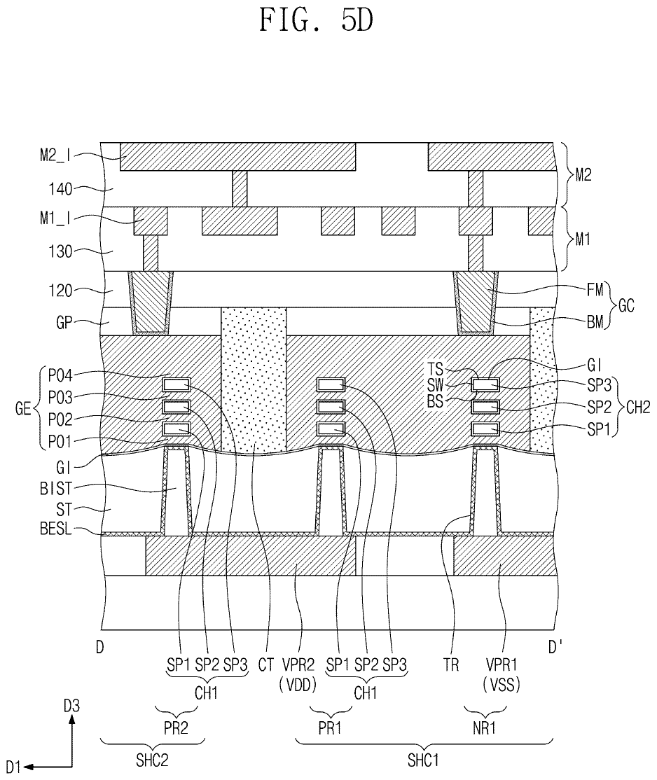

FIG. 4 is a plan view for describing a semiconductor device according to embodiments of the inventive concept. FIG. 4 is a front surface plan view from a front surface of the semiconductor device. FIGS. 5A to 5D are respectively cross-sectional views taken along line A-A′, line B-B′, line C-C′, and line D-D′ of FIG. 4 according to example embodiments. In the semiconductor device illustrated in FIG. 4, and 5A to 5D, the first and second single height cells SHC1 and SHC2 of FIG. 3 are more specifically illustrated.

Referring to FIG. 4, and 5A to 5D, the first and second single height cells SHC1 and SHC2 may be provided on the substrate 105. Logic transistors that constitute a logic circuit may be disposed on each of the first and second single height cells SHC1 and SHC2. The substrate 105 may include a silicon-based insulating layer and may include, for example, a silicon oxide layer, a silicon nitride layer or a silicon oxynitride layer. For another example, the substrate 105 may be a semiconductor substrate including silicon, germanium, silicon-germanium, or the like, or a compound semiconductor substrate. For example, the substrate 105 may be a silicon substrate. Lower power wires VPR1 to VPR3 to be described later may be disposed under the substrate 105.

The substrate 105 may have the first PMOSFET region PR1, the second PMOSFET region PR2, the first NMOSFET region NR1, and the second NMOSFET region NR2. Each of the first PMOSFET region PR1, the second PMOSFET region PR2, the first NMOSFET region NR1, and the second NMOSFET region NR2 may extend in the second direction D2. The first single height cell SHC1 may include the first NMOSFET region NR1 and the first PMOSFET region PR1, and the second single height cell SHC2 may include the second PMOSFET region PR2 and the second NMOSFET region NR2.

A rear surface separation pattern BIST may be defined by a trench TR formed on the substrate 105. The rear surface separation pattern BIST may be provided on each of the first and second PMOSFET regions PR1 and PR2, and on each of the first and second NMOSFET regions NR1 and NR2.

A device separation layer ST may fill the trench TR. The device separation layer ST may be provided on a sidewall of the rear surface separation pattern BIST. The device separation layer ST may include a silicon oxide layer. The device separation layer ST may not cover first and second channel patterns CH1 and CH2 to be described later.

A first channel pattern CH1 may be provided on the rear surface separation pattern BIST on the first and second PMOSFET regions PR1 and PR2. A second channel pattern CH2 may be provided on the rear surface separation pattern BIST on the first and second NMOSFET regions NR1 and NR2. Each of the first channel pattern CH1 and the second channel pattern CH2 may include a first semiconductor pattern SP1, a second semiconductor pattern SP2, and a third semiconductor pattern SP3 sequentially stacked. The first to third semiconductor patterns SP1, SP2, and SP3 may be spaced apart from each other in a vertical direction (that is, the third direction D3).

Each of the first to third semiconductor patterns SP1, SP2, and SP3 may include silicon (Si), germanium (Ge), or silicon-germanium (SiGe). For example, each of the first to third semiconductor patterns SP1, SP2, and SP3 may include crystalline silicon. Each of the first to third semiconductor patterns SP1, SP2, and SP3 may be a nanosheet.

One of a plurality of first source/drain patterns SD1 may be provided on a rear surface active contact BAC to be described later. The first source/drain patterns SD1 may be respectively provided in first recesses RS1 to be described later. The first source/drain patterns SD1 may be impurity regions having a first conductive type (for example, a P-type). The first channel pattern CH1 may be interposed between a pair of first source/drain patterns SD1. For example, the stacked first to third semiconductor patterns SP1, SP2, and SP3 may connect the pair of first source/drain patterns SD1 each other.

One of a plurality of second source/drain patterns SD2 may be provided on the rear surface active contact BAC to be described later. The second source/drain patterns SD2 may be respectively provided in second recesses RS2 to be described later. The second source/drain patterns SD2 may be impurity regions having a second conductive type (for example, an N-type). The second channel pattern CH2 may be interposed between a pair of second source/drain patterns SD2. For example, the stacked first to third semiconductor patterns SP1, SP2, and SP3 may connect the pair of second source/drain patterns SD2 each other.

The first and second source/drain patterns SD1 and SD2 may be epitaxial patterns formed in a selective epitaxial growth (SEG) process. For example, an upper surface of each of the first and second source/drain patterns SD1 and SD2 may be located at the substantially same level as an upper surface of the third semiconductor pattern SP3. For another example, the upper surface of each of the first and second source/drain patterns SD1 and SD2 may be located at a higher level than the upper surface of the third semiconductor pattern SP3.

The first source/drain patterns SD1 may include a semiconductor element (for example, SiGe) having a greater lattice parameter than a semiconductor element of the first channel pattern CH1. Accordingly, the pair of the first source/drain patterns SD1 may supply a compressive stress to the first channel pattern CH1 therebetween. The second source/drain patterns SD2 may include the same semiconductor element (for example, Si) as the second channel pattern CH2.

Each of the first source/drain patterns SD1 may include a buffer layer BFL, and a main layer MAL on the buffer layer BFL. Referring back to FIG. 5A, the buffer layer BFL may cover an inner sidewall of the first recess RS1. The main layer MAL may fill the remaining region of the first recess RS1 excluding the buffer layer BFL. The main layer MAL may have a greater volume than the buffer layer BFL. Each of the main layer MAL and the buffer layer BFL may include silicon-germanium (SiGe). Specifically, the buffer layer BFL may contain germanium (Ge) at a relatively low concentration. According to another embodiment of the inventive concept, the buffer layer BFL may contain only silicon (Si) without germanium (Ge). The buffer layer BFL may have germanium (Ge) at a concentration of 0 at % to about 30 at %.

The main layer MAL may contain germanium (Ge) at a relatively high concentration. For example, the main layer MAL may have germanium (Ge) at a concentration of about 30 at % to about 70 at %. A germanium (Ge) concentration of the main layer MAL may increase in a third direction D3. For example, the main layer MAL adjacent to the buffer layer BFL may have germanium (Ge) at a concentration of about 40 at %, but an upper portion of the main layer MAL may have germanium (Ge) at a concentration of about 60 at %.

Each of the buffer layer BFL and the main layer MAL may include impurities (for example, boron, gallium, or indium) which cause the first source/drain pattern SD1 to be the P-type. Each of the buffer layer BFL and the main layer MAL may have an impurity concentration of about 1E18 atom/cm³ to about 5E22 atom/cm³. The main layer MAL may have a greater impurity concentration than the buffer layer BFL.

During a process of substituting second semiconductor layers SAL to be described later to first to third inner electrodes PO1, PO2, and PO3 of a gate electrode GE, the buffer layer BFL may protect the main layer MAL. For example, the buffer layer BFL may prevent an etching material that removes the second semiconductor layers SAL from infiltrating into and etching the main layer MAL.

The second source/drain patterns SD2 may each include silicon (Si). The second source/drain pattern SD2 may further include an impurity (for example, phosphorus, arsenic, or antimony) which cause the second source/drain pattern SD2 to be the N-type. The second source/drain pattern SD2 may have an impurity concentration of about 1E18 atom/cm³ to about 5E22 atom/cm³.

The gate electrodes GE crossing the first and second channel patterns CH1 and CH2 and extending in the first direction D1 may be provided. The gate electrodes GE may be arranged with a first pitch in the second direction D2. The gate electrodes GE may respectively vertically overlap the first and second channel patterns CH1 and CH2.

The gate electrode GE may include a first inner electrode PO1 interposed between the rear surface separation pattern BIST and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

Referring back to FIG. 5D, the gate electrode GE may be provided on an upper surface TS, a bottom surface BS, and both sidewalls SW of each of the first to third semiconductor patterns SP1, SP2, and SP3. For example, a transistor according to the present embodiment may be a three-dimensional field effect transistor (for example, a multi-bridge channel FET (MBCFET) or gate-all-around FET (GAAFET)) in which the gate electrode GE three-dimensionally surrounds a channel thereof.

Representatively, the first single height cell SHC1 may have a first boundary BD1 and a second boundary BD2 opposed to each other in the second direction D2. The first and second boundaries BD1 and BD2 may extend in the first direction D1. The first single height cell SHC1 may have a third boundary BD3 and a fourth boundary BD4 opposed to each other in the first direction D1. The third and fourth boundaries BD3 and BD4 may extend in the second direction D2.

Gate cutting patterns CT may be disposed on a boundary of each of the first and second single height cells SHC1 and SHC2 in the second direction D2. For example, the gate cutting patterns CT may be disposed on the third and fourth boundaries BD3 and BD4 of the first single height cell SHC1. The gate cutting patterns CT may be arranged with the first pitch along the third boundary BD3. The gate cutting patterns CT may be arranged with the first pitch along the fourth boundary BD4. On a plan view, the gate cutting patterns CT on the third and fourth boundaries BD3 and BD4 may be disposed so as to respectively overlap the gate electrodes GE. The gate cutting patterns CT may include an insulating material such as a silicon oxide layer, a silicon nitride layer, or a combination thereof.

The gate electrode GE on the first single height cell SHC1 and the gate electrode GE on the second single height cell SHC2 may be separated by the gate cutting pattern CT. The gate cutting pattern CT may be interposed between the gate electrode GE on the first single height cell SHC1 and the gate electrode GE on the second single height cell SHC2 aligned therewith in the first direction D1. For example, the gate electrode GE extending in the first direction D1 may be divided into a plurality of gate electrodes GE by the gate cutting patterns CT.

Referring back to FIG. 4, and 5A to 5D, a pair of gate spacers GS may be respectively disposed on both sidewalls of the outer electrode PO4 of the gate electrode GE. The gate spacers GS may extend along the gate electrode GE in the first direction D1. The gate spacers GS may have higher upper surfaces than the gate electrode GE. The upper surfaces of the gate spacers GS may be coplanar with an upper surface of a first interlayered insulating layer 110 to be described later. The gate spacers GS may include at least one of SiCN, SiCON, or SiN. For another example, the gate spacers GS may include a multi-layer composed of at least two of SiCN, SiCON, and SiN.

A gate capping pattern GP may be provided on the gate electrode GE. The gate capping pattern GP may extend along the gate electrode GE in the first direction D1. The gate capping pattern GP may include a material having etching selectivity with respect to first and second interlayered insulating layers 110 and 120 to be described later. Specifically, the gate capping pattern GP may include at least one of SiON, SiCN, SiCON, and SiN.

A gate insulating layer GI may be interposed between the gate electrode GE and the first channel pattern CH1, and between the gate electrode GE and the second channel pattern CH2. The gate insulating layer GI may cover the upper surface TS, the bottom surface BS, and the both sidewalls SW of each of the first to third semiconductor patterns SP1, SP2, and SP3. The gate insulating layer GI may cover an upper surface of the device separation layer ST under the gate electrode GE. The gate insulating layer GI may cover an upper surface of the rear surface separation pattern BIST under the gate electrode GE (see FIG. 5D). The gate insulating layer GI may be interposed between the first inner electrode PO1 and the rear surface separation pattern BIST.

According to an embodiment of the inventive concept, the gate insulating layer GI may include a silicon oxide layer, a silicon oxynitride layer, and/or a high dielectric layer. The high dielectric layer may include a material having a higher dielectric constant than the silicon oxide layer. For example, the material having a higher dielectric constant than the silicon oxide layer may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

The gate electrode GE may include a first metal pattern, and a second metal pattern on the first metal pattern. The first metal pattern may be provided on the gate insulating layer GI to be adjacent to the first to third semiconductor patterns SP1, SP2, and SP3. The first metal pattern may include work-function metal that controls a threshold voltage of a transistor. A targeted threshold voltage of the transistor may be achieved by controlling a thickness and a composition of the first metal pattern. For example, the first to third inner electrodes PO1, PO2, and PO3 of the gate electrode GE may be composed of the first metal pattern composed of the work-function metal.

The first metal pattern may include a metal nitride layer. For example, the first metal pattern may include nitrogen (N) and at least one metal selected from the group consisting of titanium (Ti), tantalum (Ta), aluminum (Al), tungsten (W), and molybdenum (Mo). Moreover, the first metal pattern may further include carbon (C). The first metal pattern may include a plurality of stacked work-function metal layers.

The second metal pattern may include metal having lower resistance than that of the first metal pattern. For example, the second metal pattern may include at least one metal selected from the group consisting of titanium (Ti), tantalum (Ta), aluminum (Al), and tungsten (W). For example, the outer electrode PO4 of the gate electrode GE may include the first metal pattern and the second metal pattern on the first metal pattern.

Referring back to FIGS. 4 and 5B, inner spacers IP may be provided on the first and second NMOSFET regions NR1 and NR2. For example, the inner spacers IP may be provided on the rear surface active contact BAC. The inner spacers IP may be respectively interposed between the second source/drain pattern SD2 and the first to third inner electrodes PO1, PO2, and PO3 of the gate electrode GE. The inner spacers IP may be in contact with the second source/drain pattern SD2. Each of the first to third inner electrodes PO1, PO2, and PO3 of the gate electrode GE may be spaced apart from the second source/drain pattern SD2 by the inner spacer IP.

The first interlayered insulating layer 110 may be provided on the substrate 105. The first interlayered insulating layer 110 may cover sidewalls of the gate spacers GS and the first and second source/drain patterns SD1 and SD2. An upper surface of the first interlayered insulating layer 110 may be substantially coplanar with an upper surface of the gate capping pattern GP and an upper surface of the gate spacer GS. The second interlayered insulating layer 120 covering the gate capping pattern GP may be disposed on the first interlayered insulating layer 110. A third interlayered insulating layer 130 may be provided on the second interlayered insulating layer 120. A fourth interlayered insulating layer 140 may be provided on the third interlayered insulating layer 130. For example, the first to fourth interlayered insulating layers 110, 120, 130, and 140 may each include a silicon oxide layer.

A pair of separation structures DB opposed to each other in the second direction D2 may be provided on both sides of each of the first and second single height cells SHC1 and SHC2. For example, the pair of separation structures DB may be respectively provided on the first and second boundaries BD1 and BD2 of the first single height cell SHC1. The separation structure DB may extend parallel to the gate electrodes GE in the first direction D1. A pitch between the separation structure DB and the gate electrodes GE adjacent thereto may be the same as the first pitch.

The separation structure DB may penetrate the gate capping pattern GP and the gate electrodes GE to extend to the inside of the rear surface active contact BAC. The separation structure DB may penetrate the rear surface active contact BAC. The separation structure DB may electrically separate an active region of each of the first and second single height cells SHC1 and SHC2 from an active region of another cell adjacent thereto.

Upper active contacts or an upper active contact AC penetrating the first and second interlayered insulating layers 110 and 120 to be respectively electrically connected to the first and second source/drain patterns SD1 and SD2 may be provided. Each of the upper active contacts AC may be provided so as to be adjacent to one side of the gate electrode GE. On a plan view, the upper active contact AC may have a form of a bar extending in the first direction D1.

The upper active contact AC may be a self-aligned contact. For example, the upper active contact AC may be formed self-aligned using the gate capping pattern GP and the gate spacer GS. For example, the upper active contact AC may at least partially cover sidewalls of the gate spacer GS. Although not shown, the upper active contact AC may partially cover an upper surface of the gate capping pattern GP.

A metal-semiconductor compound layer SC, for example, a silicide layer may be interposed between each of the upper active contact AC and the first source/drain pattern SD1, and between the upper active contact AC and the second source/drain pattern SD2. The upper active contact AC may be electrically connected to the source/drain patterns SD1 and SD2 through the metal-semiconductor compound layer SC. For example, the metal-semiconductor compound layer SC may include at least one of titanium-silicide, tantalum-silicide, tungsten-silicide, nickel-silicide, and cobalt-silicide.

Gate contacts GC penetrating the second interlayered insulating layer 120 and the gate capping pattern GP to be respectively electrically connected to the gate electrodes GE may be provided. On a plan view, two gate contacts GC on the first single height cell SHC1 may be disposed so as to overlap the first PMOSFET region PR1. On a plan view, one gate contact GC on the first single height cell SHC1 may be disposed so as to overlap the first NMOSFET region NR1.

The gate contact GC may be freely disposed on the gate electrode GE without limitation of a position. For example, the gate contacts GC on the second single height cell SHC2 may be respectively disposed on the second PMOSFET region PR2, the second NMOSFET region NR2, and the device separation layer ST that fills the trench TR (see FIG. 4).

According to an embodiment of the inventive concept, referring to FIGS. 5A and 5B, the gate contact GC may be in contact with an upper surface of the outer electrode PO4. An upper portion of the upper active contact AC adjacent to the gate contact GC may be filled with an upper insulating pattern UIP. The upper insulating pattern UIP may have a lower bottom surface than the gate contact GC. For example, an upper surface of the upper active contact AC adjacent to the gate contact GC may become lower than a bottom surface of the gate contact GC due to the upper insulating pattern UIP. Accordingly, a short circuit occurring when the gate contact GC is in contact with the upper active contacts AC adjacent thereto may be prevented. For example, the upper insulating pattern UIP may include a silicon-based insulating material (for example, a silicon oxide layer, a silicon nitride layer, or a silicon oxynitride layer).

Each of the upper active contact AC and the gate contact GC may include a conductive pattern FM and a barrier pattern BM surrounding the conductive pattern FM. For example, the conductive pattern FM may include at least one metal of aluminum, copper, tungsten, molybdenum, and cobalt. The barrier pattern BM may cover sidewalls and a bottom surface of the conductive pattern FM. The barrier pattern BM may include a metal layer/metal nitride layer. The metal layer may include at least one of titanium, tantalum, tungsten, nickel, cobalt and platinum. The metal nitride layer may include at least one of a titanium nitride (TiN) layer, a tantalum nitride (TaN) layer, a tungsten nitride (WN) layer, a nickel nitride (NiN) layer, a cobalt nitride (CoN) layer, and a platinum nitride (PtN) layer.

Referring back to FIG. 4, and 5A to 5D, the first to third lower power wires VPR1, VPR2, and VPR3 may be provided in a lower portion of the substrate 105. Specifically, the first to third lower power wires VPR1, VPR2 and VPR3 may be buried in the lower portion of the substrate 105. The first to third lower power wires VPR1, VPR2, and VPR3 may extend parallel to each other in the second direction D2. The first lower power wire VPR1 may be disposed on the fourth boundary BD4 of the first single height cell SHC1. The second lower power wire VPR2 may be disposed on the third boundary BD3 of the first single height cell SHC1. For example, the first single height cell SHC1 may be defined between the first lower power wire VPR1 and the second lower power wire VPR2. The second single height cell SHC2 may be defined between the second lower power wire VPR2 and the third lower power wire VPR3.

According to an embodiment of the inventive concept, the first lower power wire VPR1 may vertically overlap the first NMOSFET region NR1. The second lower power wire VPR2 may vertically overlap the first PMOSFET region PR1 and the second PMOSFET region PR2. The third lower power wire VPR3 may vertically overlap the second NMOSFET region NR2.

The first to third lower power wires VPR1, VPR2, and VPR3 may include at least one selected from the group consisting of copper, molybdenum, tungsten, and ruthenium.

A power transmission network layer PDN may be provided on a bottom surface of the substrate 105. The power transmission network layer PDN may include a plurality of lower wires electrically connected to the first to third lower power wires VPR1, VPR2, and VPR3. For example, the power transmission network layer PDN may include a wire network for applying the source voltage VSS to the first and third lower power wires VPR1 and VPR3. The power transmission network layer PDN may include a wire network for applying the drain voltage VDD to the second lower power wire VPR2.

Referring back to FIG. 4, and 5A to 5C, the rear surface active contact BAC penetrating the substrate 105 to vertically extend from the second lower power wire VPR2 to the first source/drain pattern SD1 may be provided. The rear surface active contact BAC penetrating the substrate 105 to vertically extend from the first lower power wire VPR1 to the second source/drain pattern SD2 may be provided.

Specifically, the rear surface active contact BAC disposed under the first source/drain pattern SD1 or the second source/drain pattern SD2 may have a shape in which an upper width thereof is great. For example, the rear surface active contact or each of rear surface active contacts BAC may have a shape of a bar or plate extending between a pair of separation structures DB in the second direction D2 on a plan view. On a plan view, each of the rear surface active contacts BAC may have a shape of a bar or plate separated by the rear surface separation pattern BIST to be described later.

The rear surface active contact BAC may vertically extend to the first source/drain pattern SD1 or the second source/drain patterns SD2. Specifically, the rear surface active contact BAC may include a body portion and a protrusion portion on the body portion. The body portion may be buried between the rear surface separation patterns BIST or between the rear surface separation pattern BIST and the separation structure DB to be electrically connected to the lower power wires VPR1, VPR2, and VPR3 to be described later. The protrusion portion may penetrate a pillar protection pattern BESL to be described later to be electrically connected to the first and second source/drain patterns SD1 and SD2.

For another example, the rear surface active contact BAC may have a form of a conductive column vertically and electrically connecting the second lower power wire VPR2 and the first source/drain pattern SD1, or the first lower power wire VPR1 and the second source/drain pattern SD2. The drain voltage VDD may be applied to the first source/drain pattern SD1 through the rear surface active contact BAC, and the source voltage VSS may be applied to the second source/drain pattern SD2 through the rear surface active contact BAC. For example, the second source/drain pattern SD2 may be grounded through the rear surface active contact BAC.

Referring to FIGS. 5A and 5B, the pillar protection pattern BESL may be provided between the rear surface active contact BAC and the first source/drain pattern SD1 or the second source/drain pattern SD2 in contact with the upper active contact AC. The first source/drain pattern SD1 or the second source/drain pattern SD2 in contact with the upper active contact AC may not be electrically connected to the rear surface active contact BAC due to the pillar protection pattern BESL. The upper surface of the rear surface active contact BAC not electrically connected to the first source/drain pattern SD1 or the second source/drain pattern SD2 may have a partially recessed shape along the lower surface of the first source/drain pattern SD1 or the second source/drain pattern SD2.

Although not shown, the metal-semiconductor compound layer may be provided between each of the rear surface active contacts BAC and the source/drain pattern SD1 or SD2. For example, the metal-semiconductor compound layer may be a silicide layer. The rear surface active contact BAC may be electrically connected to the first source/drain pattern SD1 or the second source/drain pattern SD2 through the metal-semiconductor compound layer. For example, the metal-semiconductor compound layer may include at least one of titanium-silicide, tantalum-silicide, tungsten-silicide, nickel-silicide, and cobalt-silicide.

The rear surface active contacts BAC may include a rear surface conductive pattern and a rear surface barrier pattern surrounding the rear surface conductive pattern. The rear surface barrier pattern may cover sidewalls and an upper surface of the rear surface conductive pattern. For example, the rear surface conductive pattern may include at least one metal of aluminum, copper, tungsten, molybdenum, and cobalt. The rear surface barrier pattern may cover the sidewalls and the upper surface of the rear surface conductive pattern. The rear surface barrier pattern may include a metal layer/metal nitride layer. The metal layer may include at least one of titanium, tantalum, tungsten, nickel, cobalt, and platinum. The metal nitride layer may include at least one of a titanium nitride (TiN) layer, a tantalum nitride (TaN) layer, a tungsten nitride (WN) layer, a nickel nitride (NiN) layer, a cobalt nitride (CoN) layer, and a platinum nitride (PtN) layer. The rear surface conductive pattern may include the same material as the conductive pattern FM of the upper active contact AC and the gate contact GC, and the rear surface barrier pattern may include the same material as the barrier pattern BM of the upper active contact AC and the gate contact GC.

The rear surface separation pattern BIST penetrating the rear surface active contact BAC may be provided under the gate electrode GE. The rear surface separation pattern BIST may extend from an upper surface of the lower power wire VPR1 or VPR2 to a bottom surface of the gate insulating layer GI surrounding the first inner electrode PO1. Specifically, the rear surface separation pattern BIST may extend from the upper surface of the lower power wire VPR1 or VPR2 to a bottom surface of the pillar protection pattern BESL to be described later. For example, the rear surface separation pattern BIST may be spaced apart from the gate insulating layer GI by the pillar protection pattern BESL to be described later.

A width in the second direction D2 of the rear surface separation pattern BIST may become smaller toward the third direction D3. For example, a width of the upper surface of the rear surface separation pattern BIST may be smaller than a width of a lower surface of the rear surface separation pattern BIST. The maximum width in the second direction D2 of the rear surface separation pattern BIST may be smaller than the maximum width in the second direction D2 of each of the first to third inner electrodes PO1, PO2, and PO3 of the gate electrode GE.

The rear surface separation pattern BIST may penetrate the rear surface active contact BAC to be formed, and thus the rear surface active contact BAC may be separated respectively corresponding to the source/drain patterns SD1 or SD2. For example, the rear surface separation pattern BIST may separate the rear surface active contact BAC electrically connected to the source/drain pattern SD1 or SD2 into units in a transistor. The rear surface separation pattern BIST may electrically separate the rear surface active contact BAC into the units so as to individually select the source/drain pattern SD1 or SD2 to which the drain voltage VDD or source voltage VSS is applied.

Referring back to FIGS. 5A and 5B, a pillar protection pattern BESL may be provided between the body portion of the rear surface active contact BAC and the source/drain pattern SD1 or SD2, and between the gate electrode GE and the rear surface separation pattern BIST. The pillar protection pattern BESL may cover a lower portion of the separation structures DB. Specifically, the pillar protection pattern BESL may extend from one side surface of a lower portion of the separation structures DB through a lower surface of the lower portion of the separation structures DB to the other side surface of the lower portion of the separation structures DB.

More specifically, according to a manufacturing method to be described later, the pillar protection pattern BESL may be formed in a shape in which the pillar protection pattern BESL extends onto the lower portion of the separation structures DB, a lower surface of the source/drain pattern SD1 or SD2 and the lower surface of the gate electrode GE. The pillar protection pattern BESL may be separated by a protrusion portion of the rear surface active contact BAC in a process of forming the rear surface active contact BAC.

According to an embodiment of the inventive concept, the pillar protection pattern BESL may be interposed between the rear surface separation pattern BIST and the first inner electrode PO1 of the electrode GE. Specifically, the pillar protection pattern BESL may be interposed between the rear surface separation pattern BIST and the gate insulating layer GI surrounding the first inner electrode PO1. The pillar protection pattern BESL may be interposed between the gate insulating layer GI and the rear surface separation pattern BIST, and thus the high-dielectric layer of the gate insulating layer GI may be prevented from being damaged. For example, the pillar protection pattern BESL may prevent loss or damage of the high-dielectric layer occurring in an etching process of forming the rear surface separation pattern BIST to be described later. Accordingly, reliability of the semiconductor device according to the inventive concept may be improved.

The rear surface separation pattern BIST and the pillar protection pattern BESL may respectively include different insulating materials. The insulating material may include SiO₂, SiN, SiOC, SiCN, TiO₂ or a combination thereof. Specifically, the rear surface separation pattern BIST may include at least one of SiO₂, SiN, SiOC, SiCN, and TiO₂, and the pillar protection pattern BESL may include one of SiO₂, SiN, SiOC, SiCN, and TiO₂, different from the rear surface separation pattern BIST. Hereinafter, the rear surface separation pattern BIST and the pillar protection pattern BESL will be described in detail later.

Referring back to FIG. 4, and 5A to 5D, a first metal layer M1 may be provided in the third interlayered insulating layer 130. The first metal layer M1 may include first wires M1_I. The first wires M1_I of the first metal layer M1 may extend parallel to each other in the second direction D2.

According to embodiments of the inventive concept, a power wire for supplying power to the single height cell SHC may be provided under the substrate 105 in a form of the lower power wires VPR1, VPR2, and VPR3. For another example, the lower power wires VPR1, VPR2, and VPR3 may be buried in the substrate 105. Accordingly, the power wire may be omitted in the first metal layer M1. The first wires M1_I for signal transmission may be disposed in the first metal layer M1.

The first metal layer M1 may further include first vias (or a first via) VI1. The first vias VI1 may be respectively provided under the first wires M1_I of the first metal layer M1. The upper active contact AC and the first wire M1_I of the first metal layer M1 may be electrically connected to each other through the first via VI1. For example, a signal may be transmitted to or from the first source/drain pattern SD1 or the second source/drain pattern SD2 through the upper active contact AC, the first via VI1, and the first wire M1_I. The gate contact GC and the first wire M1_I of the first metal layer M1 may be electrically connected to each other through the first via VI1. For example, a signal may be transmitted to the gate electrode GE through the first wire M1_I, the first via VI1, and the gate contact GC.

The first wire M1_I of the first metal layer M1 and the first via VI1 thereunder may be respectively formed in separate processes. For example, each of the first wire M1_I of the first metal layer M1 and the first via VI1 may be formed in a single damascene process. The semiconductor device according to the present embodiment may be formed using a process of manufacturing a semiconductor device having a design rule less than about 20 nm.

A second metal layer M2 may be provided in the fourth interlayered insulating layer 140. The second metal layer M2 may include a plurality of second wires M2_I. Each of the second wires M2_I of the second metal layer M2 may have a form of a line or bar extending in the first direction D1. For example, the second wires M2_I may extend parallel to each other in the first direction D1.

The second metal layer M2 may further include second vias (or, a second via) VI2 provided under the second wires M2_I. The first wire M1_I of the first metal layer M1 and the second wire M2_I of the second metal layer M2 may be electrically connected to each other through the second via VI2. For example, the second wire M2_I of the second metal layer M2 and the second via VI2 thereunder may be formed together in a dual damascene process.

The first wire M1_I of the first metal layer M1 and the second wire M2_I of the second metal layer M2 may include the same conductive material or different conductive materials. For example, the first wire M1_I of the first metal layer M1 and the second wire M2_I of the second metal layer M2 may include at least one metal material selected from aluminum, copper, tungsten, molybdenum, ruthenium, and cobalt. Although not shown, metal layers (for example, M3, M4, M5, etc.) stacked on the fourth interlayered insulating layer 140 may be additionally disposed. Each of the stacked metal layers may include wires for routing between cells.

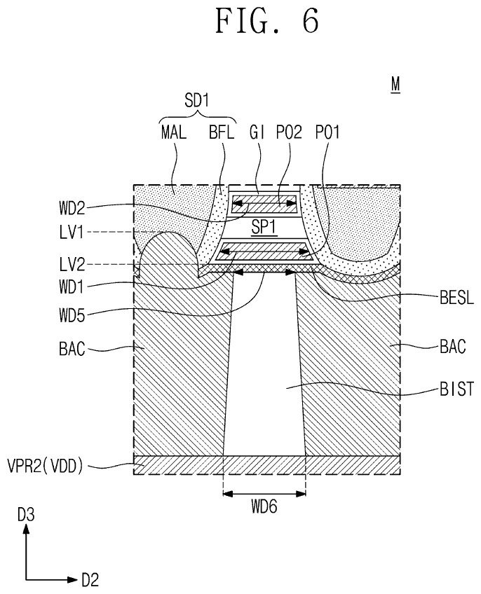

FIG. 6 is an enlarged diagram illustrating an embodiment of region M of FIG. 5A according to example embodiments. Hereinafter, the semiconductor device according to an embodiment of the inventive concept will be described with reference to FIGS. 5A and 6. In order to simplify description, duplicate description of that made above will be omitted, and a difference from that made above will be mainly described.

Referring to FIGS. 5A and 6, the gate electrode GE may have a width in the second direction D2. Specifically, the first inner electrode PO1 may have a first width WD1, and the second inner electrode PO2 may have a second width WD2. The third inner electrode PO3 may have a third width WD3, and the outer electrode PO4 may have a fourth width WD4. Each of the first to fourth widths WD1 to WD4 may be defined as the maximum width in the second direction D2 of the gate electrode GE corresponding thereto.

The first width WD1 may be greater than the second width WD2, the third width WD3 and the fourth width WD4. The second width WD2 may be greater than the third width WD3 and the fourth width WD4. The third width WD3 may be greater than the fourth width WD4.

The rear surface separation pattern BIST may have a width in the second direction D2. Specifically, the upper surface of the rear surface separation pattern BIST may have a fifth width WD5, and the lower surface of the rear surface separation pattern BIST may have a sixth width WD6. For example, the fifth width WD5 may be defined as a width in the second direction D2 of the uppermost surface of the rear surface separation pattern BIST, and the sixth width WD6 may be defined as a width in the second direction D2 of the lowermost surface of the rear surface separation pattern BIST. Since the rear surface separation pattern BIST has a tapered shape in which the width thereof becomes smaller toward the third direction D3, the fifth width WD5 may be smaller than the sixth width WD6. Accordingly, the sixth width WD6 may be the maximum width in the second direction D2 of the rear surface separation pattern BIST.

The fifth width WD5 and the sixth width WD6 may be smaller than each of the first to third widths WD1 to WD3. For example, the fifth width WD5 and the sixth width WD6 may be the same as or smaller than the fourth width WD4. For another example, the fifth width WD5 may be smaller than the fourth width WD4, and the sixth width WD6 may be greater than the fourth width WD4.

The pillar protection pattern BESL may be interposed between the upper surface of the rear surface separation pattern BIST and the lower surface of the gate insulating layer GI surrounding the first inner electrode PO1. The pillar protection pattern BESL may extend from the lower surface of the gate insulating layer GI to the lower surface of the first source/drain pattern SD1.

The rear surface separation pattern BIST may vertically overlap the pillar protection pattern BESL, the gate electrode GE and the second lower power wire VPR2. Specifically, the rear surface separation pattern BIST may vertically overlap the pillar protection pattern BESL, the first inner electrode PO1, the second inner electrode PO2, the third inner electrode PO3, the outer electrode PO4 and the second lower power wire VPR2. The rear surface separation pattern BIST may electrically separate the rear surface active contact BAC.

The rear surface active contact BAC may include a protrusion portion protruding toward the first source/drain pattern SD1. The protrusion portion may penetrate the pillar protection pattern BESL to be formed, and an uppermost surface of the protrusion portion may be in contact with the main layer MAL of the first source/drain pattern SD1.

The uppermost surface of the rear surface active contact BAC may be located at a first level LV1 in the third direction D3. The uppermost surface of the pillar protection pattern BESL may be located at a second level LV2 in the third direction D3. The first level LV1 may be higher than an upper surface of the first inner electrode PO1, and may be lower than a lower surface of the second inner electrode PO2. For example, the first level LV1 may be located at the same level as the first semiconductor pattern SP1 in the third direction D3. The second level LV2 may be lower than a lower surface of the first inner electrode PO1. For example, the second level LV2 may be a lower level in the third direction D3 than the first level LV1. The lowermost surface of the rear surface active contact BAC may be located at the substantially same level in the third direction D3 as the lowermost surface of the rear surface separation pattern BIST.

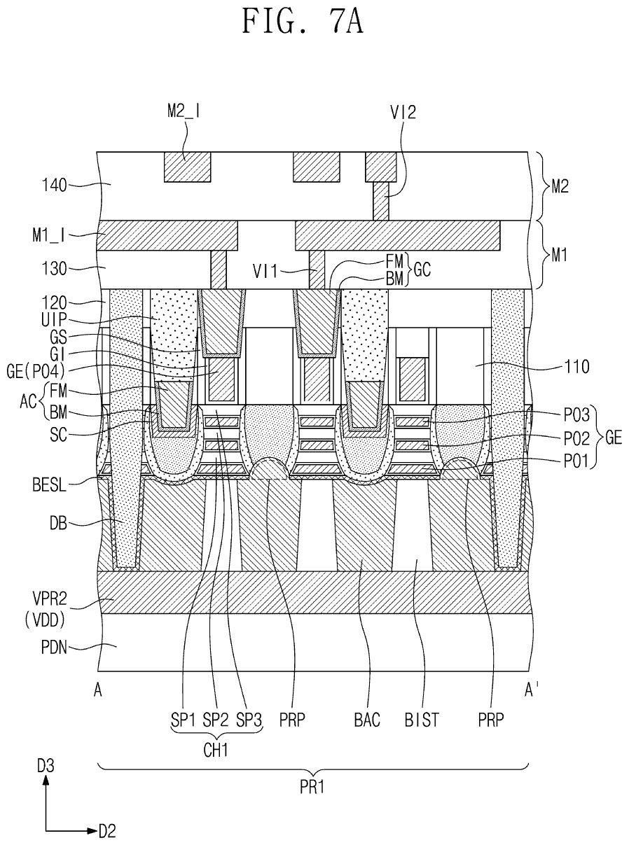

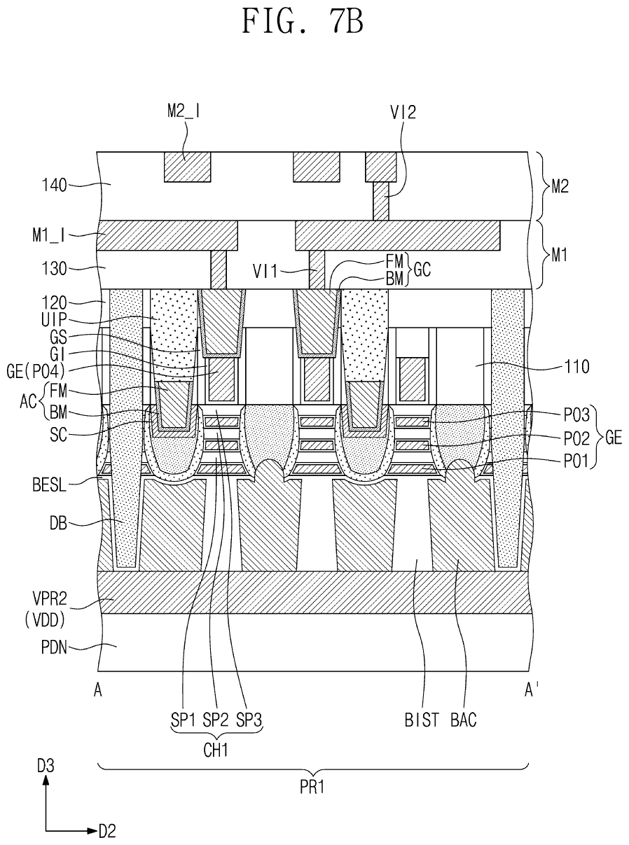

FIGS. 7A and 7B are cross-sectional views for describing the semiconductor device according to another embodiment. Hereinafter, the semiconductor device according to embodiments of the inventive concept will be described with reference to FIGS. 7A and 7B. In order to simplify description, duplicate description of that made above will be omitted, and a difference from that made above will be mainly described.

Referring to FIG. 7A, the rear surface active contact BAC may vertically extend to the first source/drain pattern SD1 not in contact with the upper active contact AC. Specifically, the rear surface active contact BAC may include a body portion and a protrusion portion PRP on the body portion. The body portion and the protrusion portion PRP may be provided between the first source/drain patterns SD1 and the second lower power wire VPR2 to electrically connect the same.

The pillar protection pattern BESL may be provided between the body portion of the rear surface active contact BAC and the first source/drain pattern SD1 in contact with the upper active contact AC. The first source/drain pattern SD1 in contact with the upper active contact AC may not be electrically connected to the rear surface active contact BAC due to the pillar protection pattern BESL. The upper surface of the rear surface active contact BAC not electrically connected to the first source/drain pattern SD1 may have a partially recessed shape along the lower surface of the first source/drain pattern SD1.

The pillar protection pattern BESL may extend onto the lower surface of the first source/drain pattern SD1 in contact with the upper active contact AC. The pillar protection pattern BESL may extend onto the protrusion portion PRP of the rear surface active contact BAC. For example, the pillar protection pattern BESL may extend onto the lower surface of the first source/drain pattern SD1 and the lower surface of the gate insulating layer GI, and may be separated by the protrusion portion PRP of the rear surface active contact BAC.

The rear surface active contact BAC may have a shape of a conductive column vertically and electrically connecting the second lower power wire VPR2 and the first source/drain pattern SD1. For example, the drain voltage VDD may be applied to the first source/drain pattern SD1 through the rear surface active contact BAC.

Referring to FIG. 7B, the rear surface separation pattern BIST and the pillar protection pattern BESL may include the same insulating material. The insulating material may include SiO₂, SiN, SiOC, SiCN, TiO₂ or a combination thereof. Since the rear surface separation pattern BIST and the pillar protection pattern BESL include the same material, a boundary between the patterns may not be seen. For example, the rear surface separation pattern BIST and the pillar protection pattern BESL may be integrally formed without the boundary therebetween.

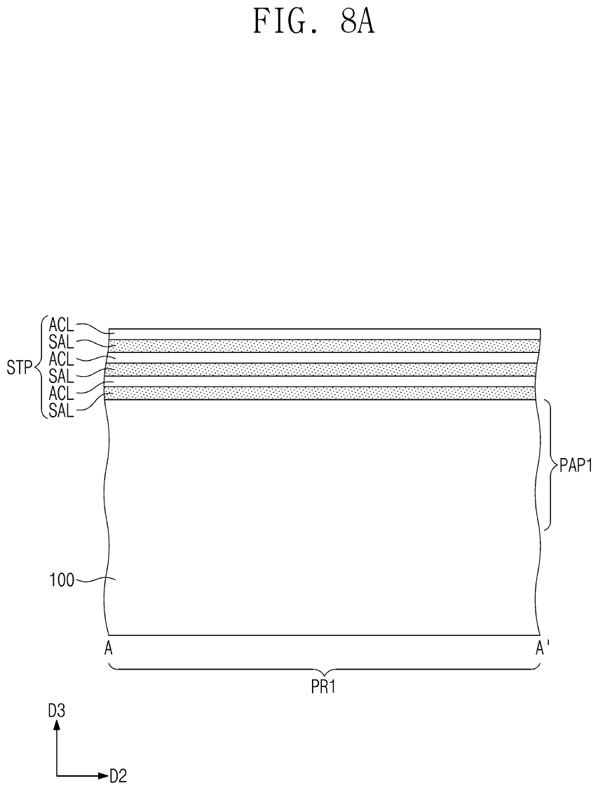

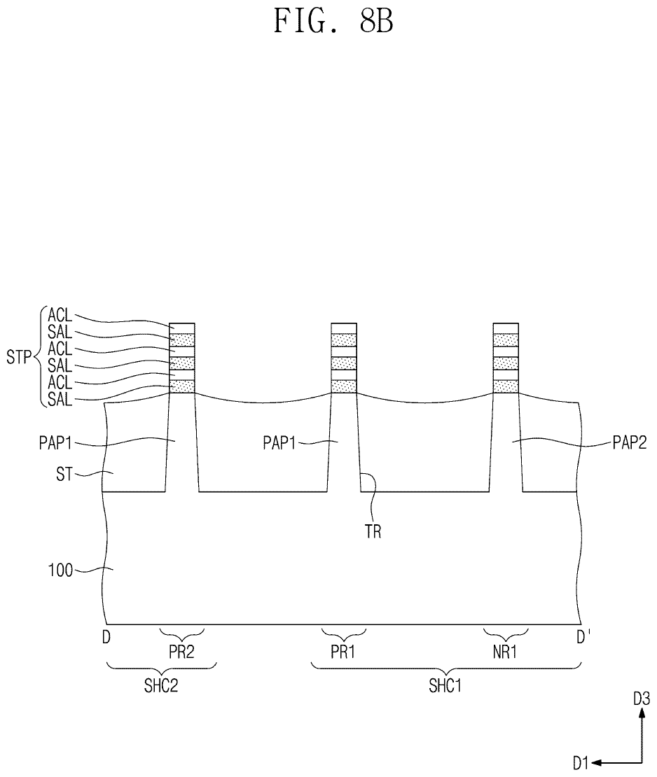

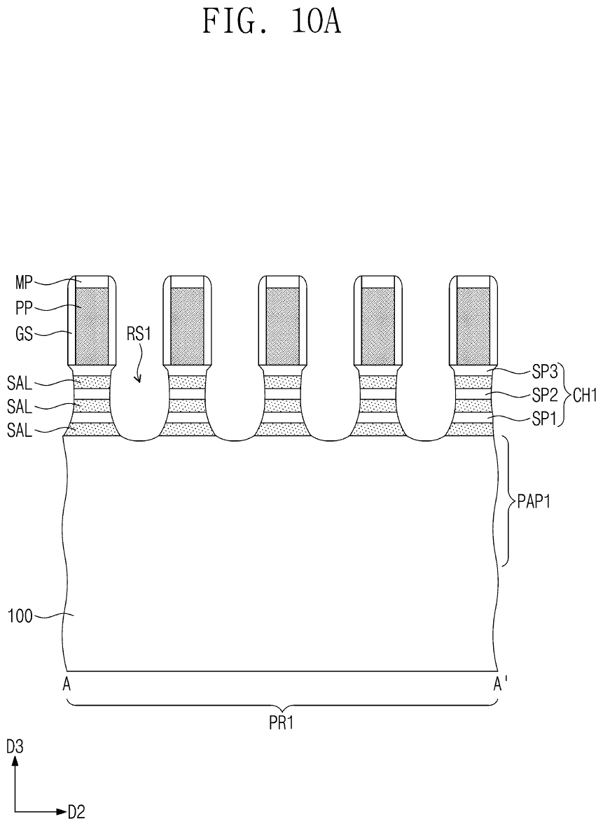

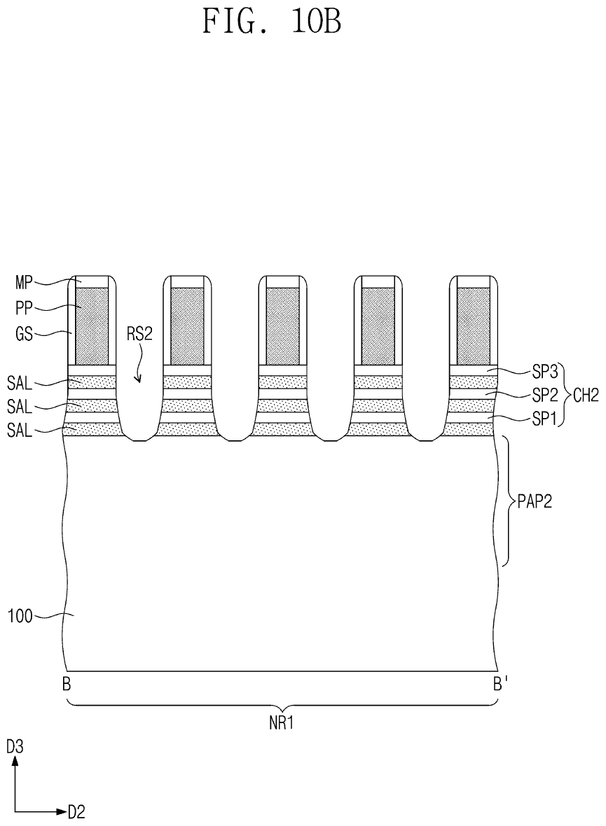

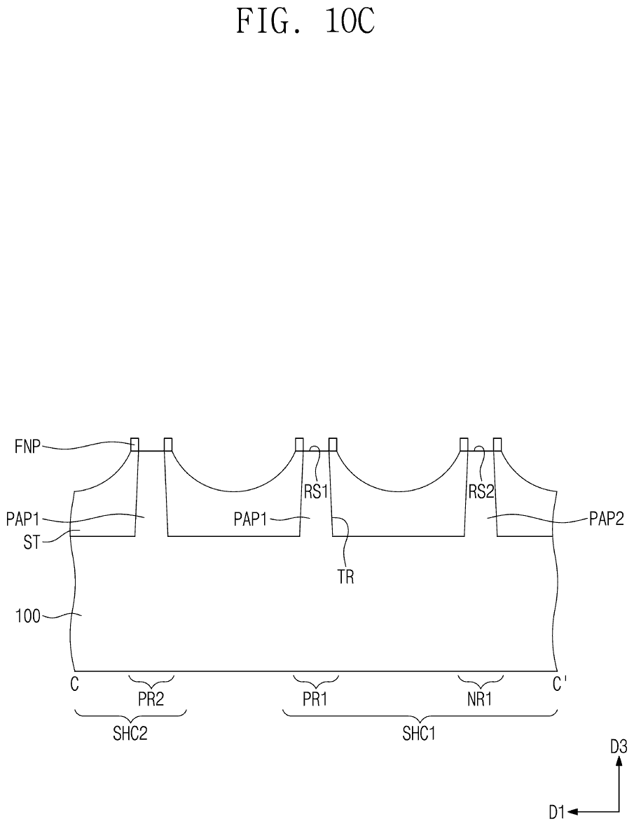

FIGS. 8A, 8B, 9A, 9B, 10A to 10C, 11A to 11C, 12A to 12C, 13A to 13D, 14A to 14D, 15A to 15D, 16A to 16D, 17A to 17D, 18A to 18D, 18A to 18D, 19A to 19D, and 20A to 20D are cross-sectional views for describing a method for manufacturing a semiconductor device according to embodiments of the inventive concept. Specifically, FIGS. 8A, 9A, 10A, 11A, 12A, 13A, 14A, 15A, 16A, 17A, 18A, 19A, and 20A are cross-sectional views corresponding to line A-A′ of FIG. 4. FIGS. 10B, 11B, 12B, 13B, 14B, 15B, 16B, 17B, 18B, 19B, and 20B are cross-sectional views corresponding to line B-B′ of FIG. 4. FIGS. 10C, 11C, 13C, 14C, 15C, 16C, 17C, 18C, 19C, and 20C are cross-sectional views corresponding to line C-C′ of FIG. 4. FIGS. 8B, 9B, 12C, 13D, 14D, 15D, 16D, 17D, 18D, 19D, and 20D are cross-sectional views corresponding to line D-D′ of FIG. 4.

Referring to FIGS. 8A and 8B, a semiconductor substrate 100 including the first and second PMOSFET regions PR1 and PR2 and the first and second NMOSFET regions NR1 and NR2 may be provided. For example, the semiconductor substrate 100 may be a silicon wafer.

First semiconductor layers ACL and second semiconductor layers SAL alternately stacked may be formed on the semiconductor substrate 100. The first semiconductor layers ACL may include one among silicon (Si), germanium (Ge), and silicon-germanium (SiGe), and the second semiconductor layers SAL may include another one among silicon (Si), germanium (Ge), and silicon-germanium (SiGe).

The second semiconductor layer SAL may include a material having etching selectivity with respect to the first semiconductor layer ACL. For example, the first semiconductor layers ACL may include silicon (Si), and the second semiconductor layers SAL may include silicon-germanium (SiGe). Each of the second semiconductor layers SAL may have germanium (Ge) at a concentration of about 10 at % to about 35 at %.

Mask patterns may be respectively formed on the first and second PMOSFET regions PR1 and PR2 and the first and second NMOSFET regions NR1 and NR2 of the semiconductor substrate 100. The mask pattern may have a form of a line or bar extending in the second direction D2.

A trench TR defining a first active pattern PAP1 and a second active pattern PAP2 may be formed by performing a patterning process using the mask patterns as etching masks. The first active pattern PAP1 may be formed on each of the first and second PMOSFET regions PR1 and PR2. The second active pattern PAP2 may be formed on each of the first and second NMOSFET regions NR1 and NR2. On a plan view, the first and second active patterns PAP1 and PAP2 may have a form of lines extending parallel to each other in the second direction D2.

A stack pattern STP may be formed on each of the first and second active patterns PAP1 and PAP2. The stack pattern STP may further include the first semiconductor layers ACL and the second semiconductor layers SAL alternately stacked on the first and second active patterns PAP1 and PAP2. The stack pattern STP may be formed together with the first and second active patterns PAP1 and PAP2 during the patterning process.

A device separation layer ST that fills the trench TR may be formed. Specifically, an insulating layer covering the first and second active patterns PAP1 and PAP2 and the stack patterns STP may be formed on a front surface of the semiconductor substrate 100. The device separation layer ST may be formed by recessing the insulating layer until the stack patterns STP are exposed.

The device separation layer ST may include an insulating material such as a silicon oxide layer. The stack patterns STP may be exposed onto the device separation layer ST. For example, the stack patterns STP may vertically protrude onto the device separation layer ST.

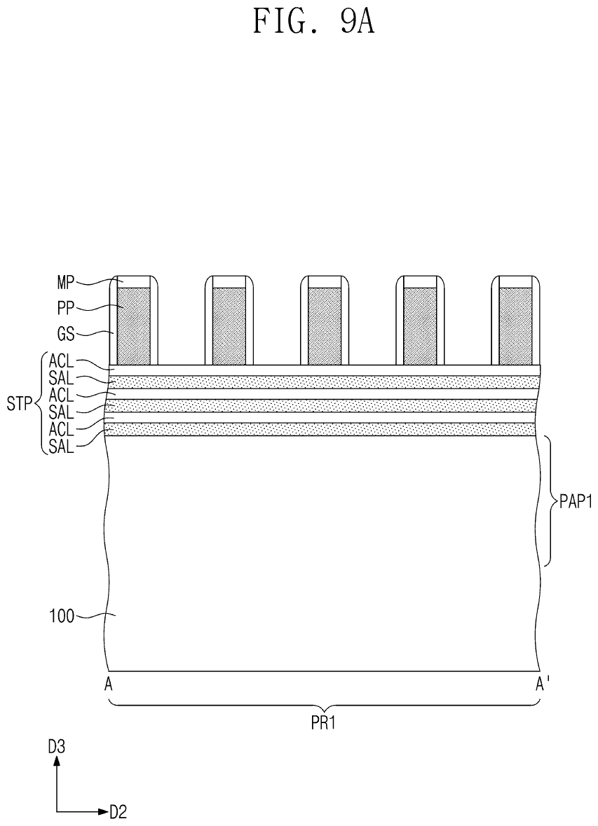

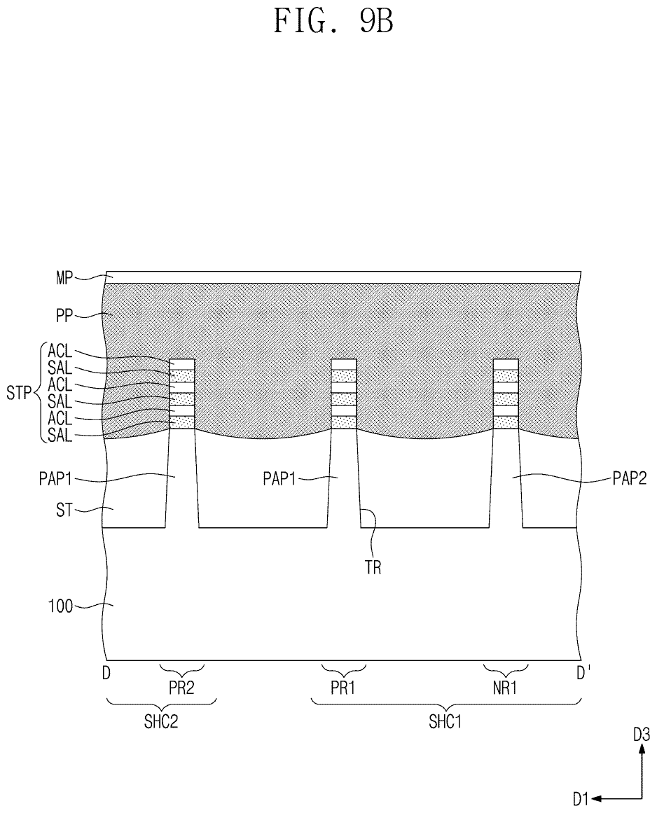

Referring to FIGS. 9A and 9B, sacrificial patterns PP crossing the stack patterns STP may be formed on the semiconductor substrate 100. Each of the sacrificial patterns PP may be formed in a form of a line or bar extending in the first direction D1. The sacrificial patterns PP may be arranged with a first pitch along the second direction D2.

Specifically, forming the sacrificial patterns PP may include forming a sacrificial layer on the front surface of the semiconductor substrate 100, forming hardmask patterns MP on the sacrificial layer, and patterning the sacrificial layer using the hardmask patterns MP as etching masks. The sacrificial layer may include polysilicon.

A pair of gate spacers GS may be formed on both sidewalls of each of the sacrificial patterns PP. Forming the gate spacers GS may include conformally forming a gate spacer layer on the front surface of the semiconductor substrate 100, and anisotropically etching the gate spacer layer. The gate spacer layer may include at least one of SiCN, SiCON, and SiN. For another example, the gate spacer layer may be a multi-layer including at least two of SiCN, SiCON, and SiN.

Referring to FIGS. 10A to 10C, first recesses RS1 may be formed in the stack pattern STP on the first active pattern PAP1. Second recesses RS2 may be formed in the stack pattern STP on the second active pattern PAP2. While the first and second recesses RS1 and RS2 are formed, the device separation layer ST on both sides of each of the first and second active patterns PAP1 and PAP2 may be further recessed. (see FIG. 10C).

Specifically, the first recesses RS1 may be formed by etching the stack pattern STP on the first active pattern PAP1 using the hardmask patterns MP and the gate spacers GS as etching masks. The first recess RS1 may be formed between a pair of sacrificial patterns PP. The second recesses RS2 in the stack pattern STP on the second active pattern PAP2 may be formed in the same process as a process of forming the first recesses RS1.

Referring back to FIG. 10C, a fence pattern FNP may be formed on each of the first and second active patterns PAP1 and PAP2. The fence pattern FNP may be a part of the remaining gate spacer GS.

Referring back to FIGS. 10A to 10C, the first to third semiconductor patterns SP1, SP2, and SP3 sequentially stacked between the first recesses RS1 adjacent to each other may be respectively formed from the first semiconductor layers ACL. The first to third semiconductor patterns SP1, SP2, and SP3 sequentially stacked between the second recesses RS2 adjacent to each other may be respectively formed from the first semiconductor layers ACL. The first to third semiconductor patterns SP1, SP2, and SP3 between the first recesses RS1 adjacent to each other may constitute the first channel pattern CH1. The first to third semiconductor patterns SP1, SP2, and SP3 between the second recesses RS2 adjacent to each other may constitute the second channel pattern CH2.

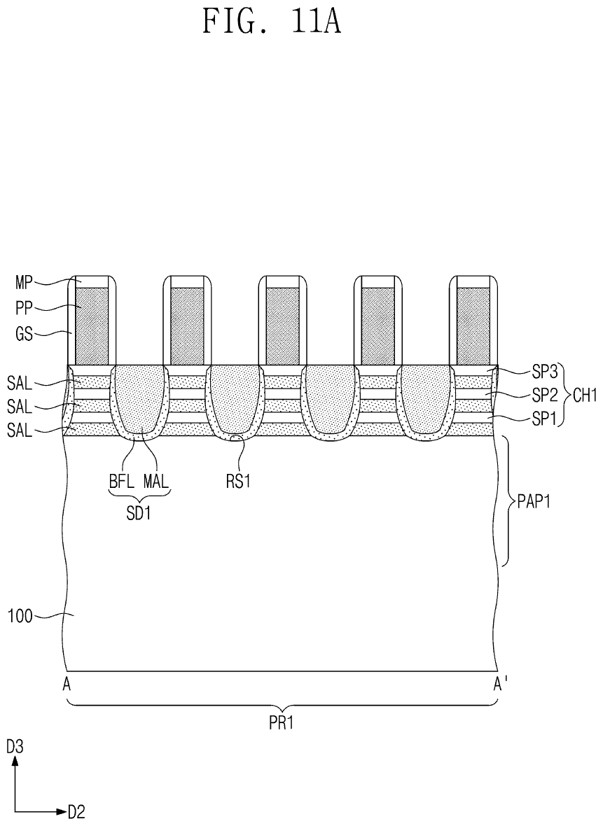

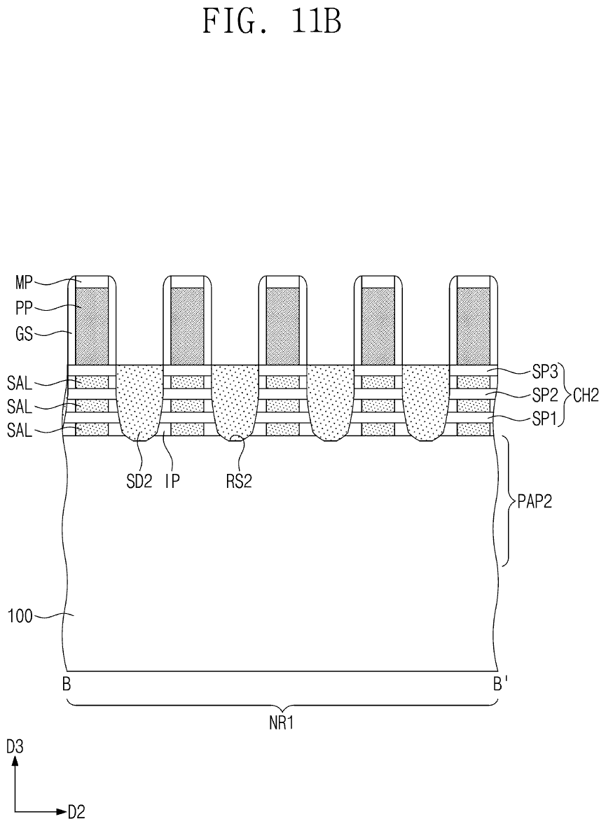

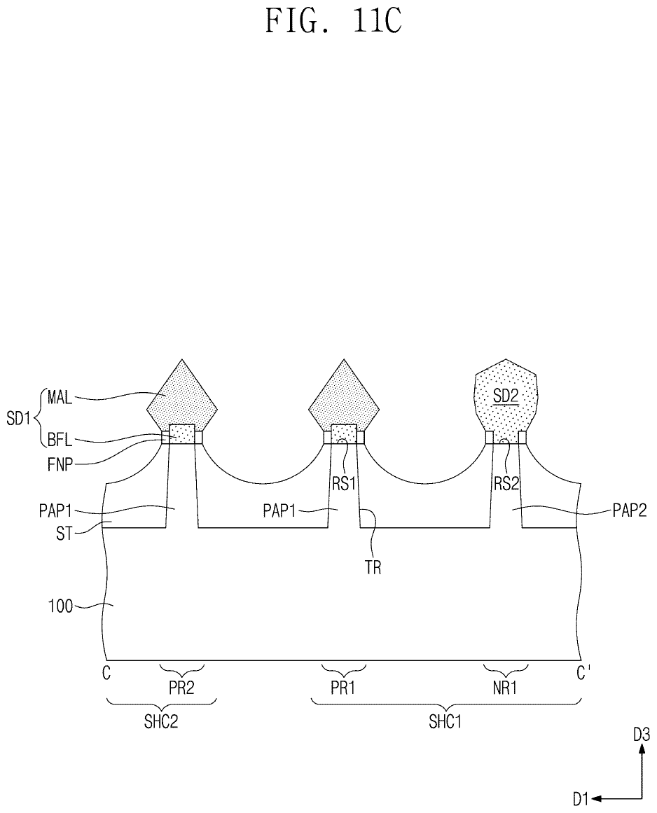

Referring to FIGS. 11A to 11C, the first source/drain patterns SD1 may be respectively formed in the first recesses RS1. Specifically, the buffer layer BFL may be formed by performing a first SEG process in which an inner sidewall of the first recess RS1 is used as a seed layer. The buffer layer BFL may be grown using, as seeds, the semiconductor substrate 100 and the first to third semiconductor patterns SP1, SP2, and SP3 exposed by the first recess RS1. For example, the first SEG process may include a chemical vapor deposition (CVD) process or molecular beam epitaxy (MBE) process.

The buffer layer BFL may include a semiconductor element (for example, SiGe) having a greater lattice parameter than a semiconductor element of the semiconductor substrate 100. The buffer layer BFL may contain germanium (Ge) at a relatively low concentration. According to another embodiment of the inventive concept, the buffer layer BFL may contain only silicon (Si) excluding germanium (Ge). For example, the buffer layer BFL may have germanium (Ge) at a concentration of 0 at % to about 30 at %.

The main layer MAL may be formed by performing a second SEG process on the buffer layer BFL. The main layer MAL may be formed so as to completely or almost fill the first recess RS1. The main layer MAL may contain germanium (Ge) at a relatively high concentration. For example, the main layer MAL may have germanium (Ge) at a concentration of about 30 at % to about 70 at %.

According to an embodiment of the inventive concept, a capping layer may be formed by performing a third SEG process on the main layer MAL. The capping layer may include silicon (Si). The capping layer may have silicon (Si) at a concentration of about 98 at % to 100 at %.

While the buffer layer BFL and the main layer MAL are formed, an impurity (for example, boron, gallium, or indium) which causes the first source/drain pattern SD1 to be a P-type may be in-situ injected. For another example, after the first source/drain pattern SD1 is formed, the impurity may be injected into the first source/drain pattern SD1.

The second source/drain patterns SD2 may be respectively formed in the second recesses RS2. Specifically, the second source/drain pattern SD2 may be formed by performing a selective epitaxial growth (SEG) process in which an inner sidewall of the second recess RS2 is used as a seed layer. For example, the second source/drain pattern SD2 may include the same semiconductor element (for example, Si) as the semiconductor substrate 100.

While the second source/drain pattern SD2 is formed, an impurity (for example, phosphorus, arsenic, or antimony) which causes the second source/drain pattern SD2 to be an N-type may be in-situ injected. For another example, after the second source/drain pattern SD2 is formed, the impurity may be injected into the second source/drain pattern SD2.

According to an embodiment of the inventive concept, before the second source/drain pattern SD2 is formed, the second semiconductor layer SAL exposed through the second recess RS2 may be partially substituted with an insulating material to form an inner spacer IP. As a result, the inner spacers IP may be respectively formed between the second source/drain pattern SD2 and the second semiconductor layers SAL.

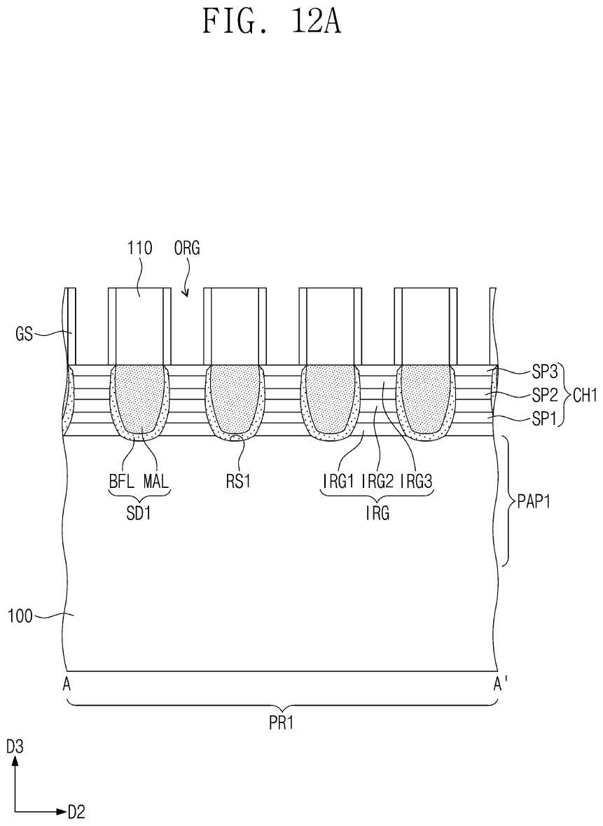

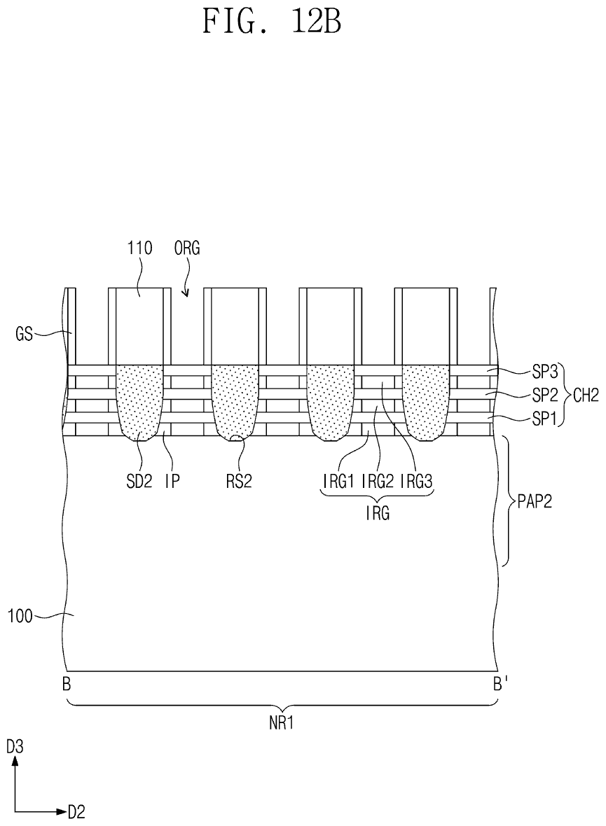

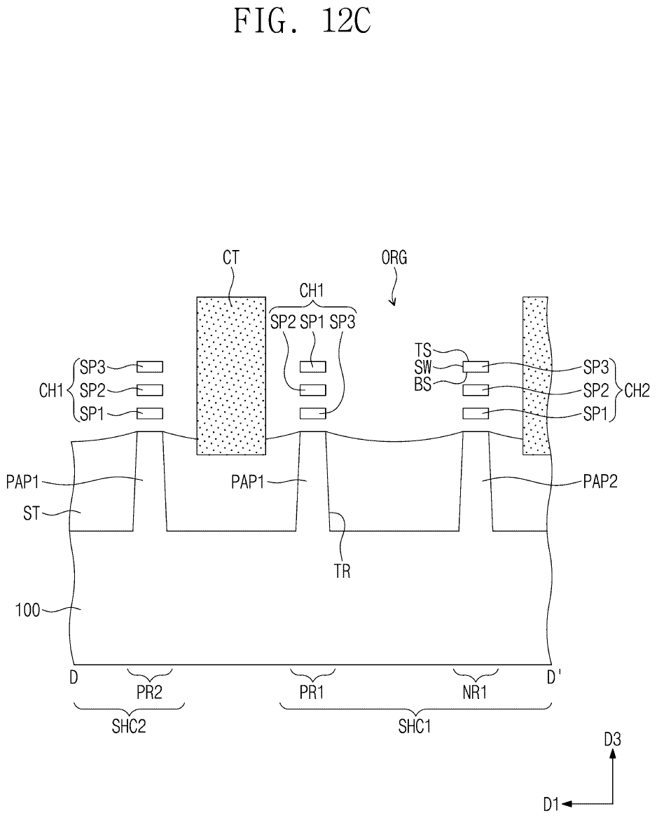

Referring to FIGS. 12A to 12C, the first interlayered insulating layer 110 covering the first and second source/drain patterns SD1 and SD2, the hardmask patterns MP, and the gate spacers GS may be formed. For example, the first interlayered insulating layer 110 may include a silicon oxide layer.

The first interlayered insulating layer 110 may be planarized until upper surfaces of the sacrificial patterns PP are exposed. The first interlayered insulating layer 110 may be planarized by using an etch-back process or a chemical mechanical polishing (CMP) process. The hardmask patterns MP may be fully removed during the planarization process. As a result, an upper surface of the first interlayered insulating layer 110 may be coplanar with the upper surfaces of the sacrificial patterns PP and the upper surfaces of the gate spacers GS.

One region of the sacrificial pattern PP may be selectively opened by using a photolithography process. For example, a region, of the sacrificial pattern PP, on the third and fourth boundaries BD3 and BD4 of the first single height cell SHC1 may be selectively opened. The opened region of the sacrificial pattern PP may be selectively removed by etching. The gate cutting pattern CT may be formed by filling the region in which the sacrificial pattern PP is removed with an insulating material (see FIG. 12C).

The exposed sacrificial patterns PP may be selectively removed. An outer region ORG exposing the first and second channel patterns CH1 and CH2 may be formed by removing the sacrificial patterns PP (see FIG. 12C). Removing the sacrificial patterns PP may include a wet etching process using an etchant selectively etching polysilicon.

Inner regions IRG may be formed by selectively removing the second semiconductor layers SAL exposed through the outer region ORG (see FIGS. 12A and 12B). Specifically, only the second semiconductor layers SAL may be removed in a state in which the first to third semiconductor patterns SP1, SP2, and SP3 remain by performing an etching process of selectively etching the second semiconductor layers SAL. The etching process may have a high etch-rate with respect to silicon-germanium having a relatively high germanium concentration. For example, the etching process may have a high etch-rate with respect to silicon-germanium having a germanium concentration higher than about 10 at %.

During the etching process, the second semiconductor layers SAL on the first and second PMOSFET regions PR1 and PR2 and the first and second NMOSFET regions NR1 and NR2 may be completely removed. The etching process may be wet etching. An etching material used in the etching process may rapidly remove the second semiconductor layer SAL having a relatively high germanium concentration. Meanwhile, the first source/drain pattern SD1 on the first and second PMOSFET regions PR1 and PR2 may be protected, during the etching process, by the buffer layer BFL having a relatively low germanium concentration.

Referring back to FIG. 12C, only the stacked first to third semiconductor patterns SP1, SP2, and SP3 may remain on each of the first and second active patterns PAP1 and PAP2 by selectively removing the second semiconductor layers SAL. First to third inner regions IRG1, IRG2, and IRG3 may be respectively formed through regions in which the second semiconductor layers SAL are removed. Specifically, a first inner region IRG1 may be formed between the active pattern PAP1 or PAP2 and the first semiconductor pattern SP1, a second inner region IRG2 may be formed between the first semiconductor pattern SP1 and the second semiconductor pattern SP2, and a third inner region IRG3 may be formed between the second semiconductor pattern SP2 and the third semiconductor pattern SP3.

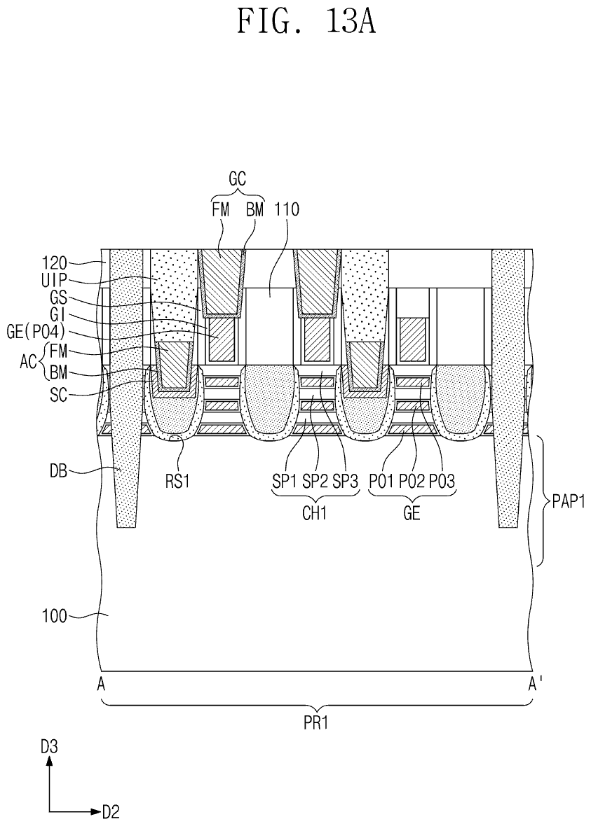

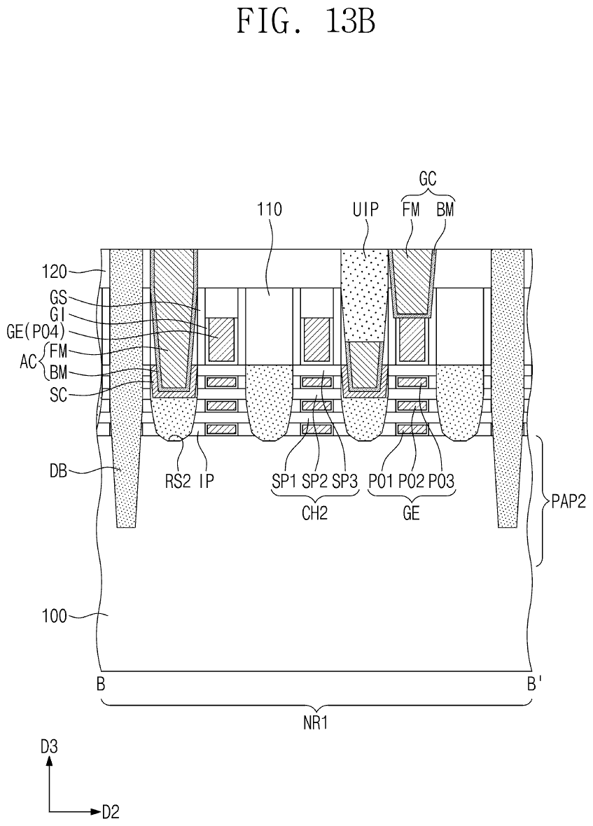

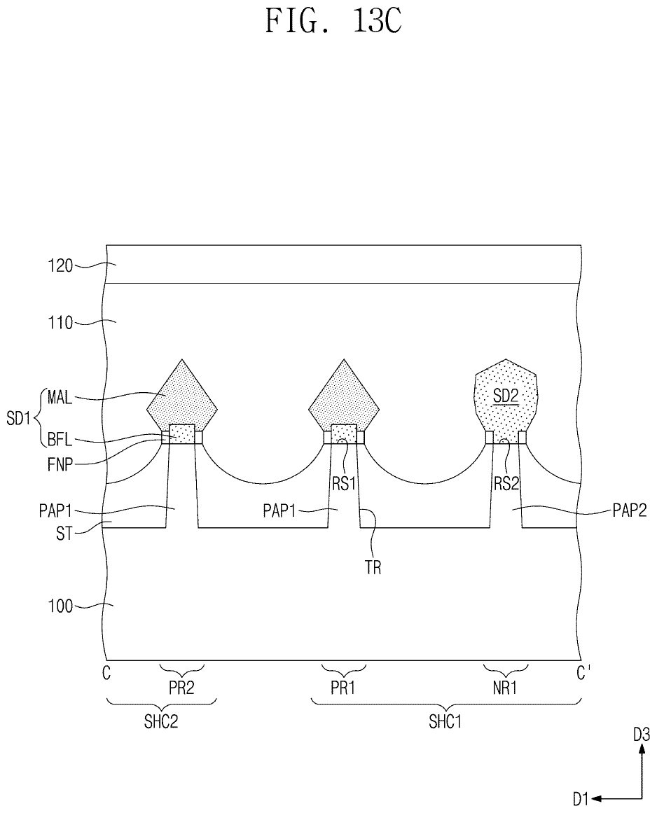

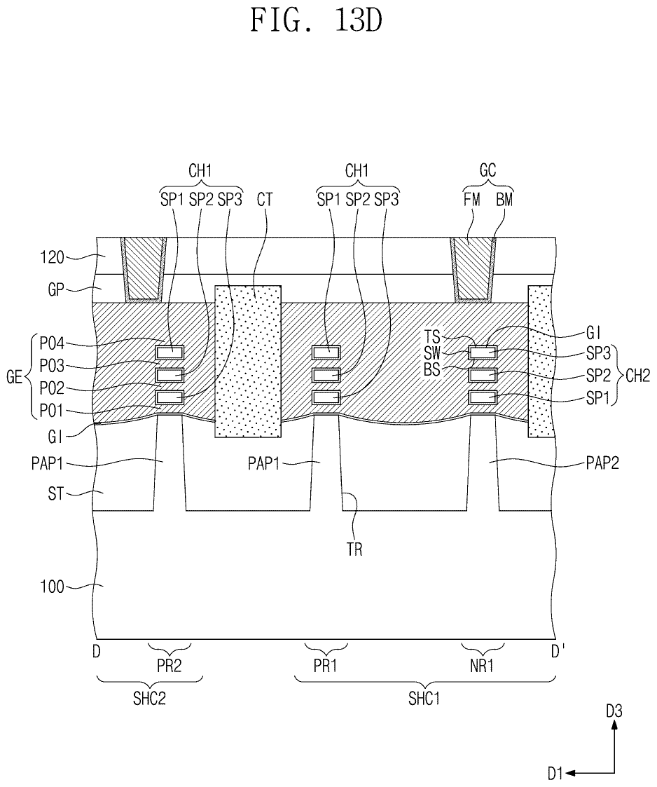

Referring to FIGS. 13A to 13D, the gate insulating layer GI may be conformally formed on the exposed first to third semiconductor patterns SP1, SP2, and SP3. The gate electrode GE may be formed on the gate insulating layer GI. The gate electrode GE may include the first to third inner electrodes PO1, PO2, and PO3 respectively formed in the first to third inner regions IRG1, IRG2, and IRG3 and the outer electrode PO4 formed in the outer region ORG.

The gate electrode GE may be recessed, and a height thereof may be reduced. While the gate electrode GE is recessed, upper parts of the gate cutting patterns CT may be also slightly recessed. The gate capping pattern GP may be formed on the recessed gate electrode GE. The gate capping pattern GP may cover the gate electrode GE and the gate cutting pattern CT.

The second interlayered insulating layer 120 may be formed on the first interlayered insulating layer 110. The second interlayered insulating layer 120 may include a silicon oxide layer. The upper active contact AC penetrating the second interlayered insulating layer 120 and the first interlayered insulating layer 110 to be electrically connected to at least one of the first and second source/drain pattern SD1 or SD2 may be formed. The gate contact GC penetrating the second interlayered insulating layer 120 and the gate capping pattern GP to be electrically connected to the gate electrode GE may be formed.

Forming each of the upper active contact AC and the gate contact GC may include forming the barrier pattern BM and forming the conductive pattern FM on the barrier pattern BM. The barrier pattern BM may be conformally formed, and may include a metal layer/metal nitride layer. The conductive pattern FM may include low resistance metal.

Referring back to FIG. 4, and 5A to 5D, the third interlayered insulating layer 130 may be formed on the upper active contacts AC and the gate contacts GC. The first metal layer M1 may be formed in the third interlayered insulating layer 130. The first metal layer M1 may include the first wire M1_I electrically connected to at least one of the upper active contacts AC and the gate contacts GC. The fourth interlayered insulating layer 140 may be formed on the third interlayered insulating layer 130. The second metal layer M2 may be formed in the fourth interlayered insulating layer 140.

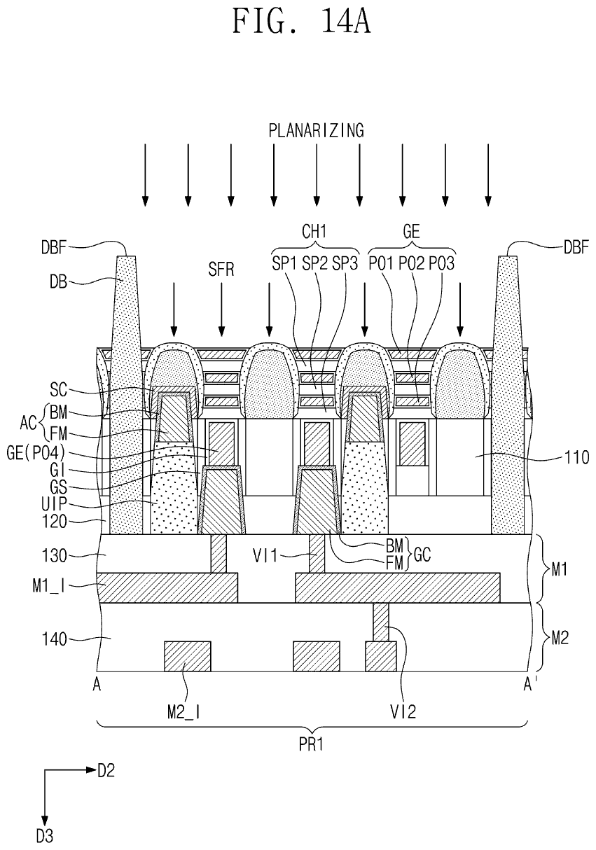

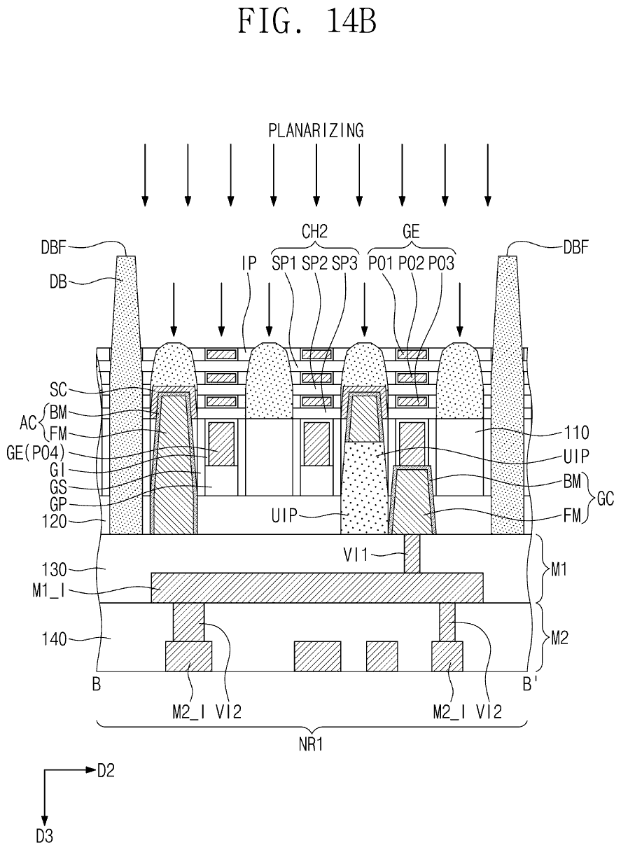

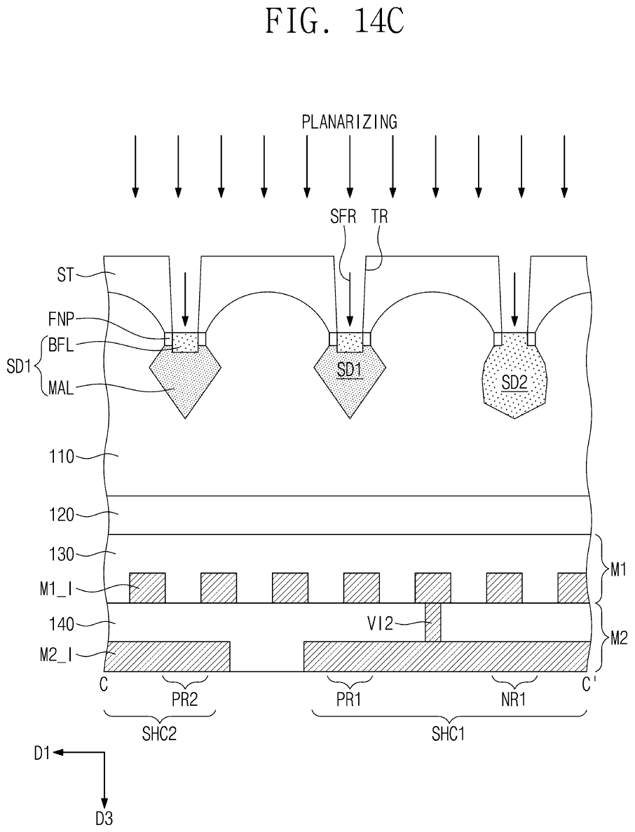

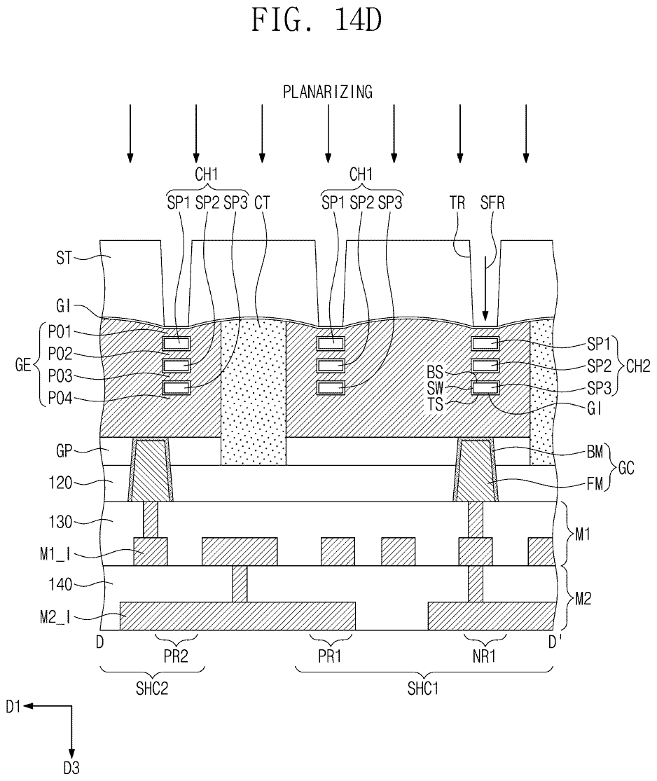

After a back end of line (BEOL) process is completed, the semiconductor substrate 100 described with reference to FIGS. 8A, 8B, 9A, 9B, 10A to 10C, 11A to 11C, 12A to 12C, 13A to 13D may be turned upside down. Since the semiconductor substrate 100 is turned upside down, hereinafter, in describing with reference to FIGS. 14A to 14D, 15A to 15D, 16A to 16D, 17A to 17D, 18A to 18D, 18A to 18D, and 20A to 20D, ‘an upper surface’ and ‘an upper part’ may respectively mean ‘a lower surface’ and ‘a lower part’ from a point of view of a completely manufactured three-dimensional semiconductor device described with reference to FIGS. 5A to 5D, and ‘a lower surface’ and ‘a lower part’ may respectively mean ‘an upper surface’ and ‘an upper part’ from the point of view of the completely manufactured three-dimensional semiconductor device described with reference to FIGS. 5A to 5D.

Referring to FIGS. 14A to 14D, after the BEOL process is completed, a bottom surface of the semiconductor substrate 100 may be exposed by turning the semiconductor substrate 100 upside down. The exposed semiconductor substrate 100 may be removed.

According to an embodiment of the inventive concept, removing the semiconductor substrate 100 may include removing one part of the semiconductor substrate 100, and removing the other part of the semiconductor substrate 100 remaining between the separation structures DB.

Removing the one part of the semiconductor substrate 100 may be reducing a thickness of the semiconductor substrate 100 by performing a planarizing process on the bottom surface of the semiconductor substrate 100. The planarizing process may be performing a chemical mechanical polishing (CMP) process using a lower surface DBF of the separation structures DB as a stop layer.

For another example, the planarizing process may be performing an etch-back process after the chemical mechanical polishing (CMP) process. Specifically, the planarizing process may be performing the chemical mechanical polishing (CMP) process for a certain time so as not to expose the separation structure DB, and then performing the etch-back process until the lower surface DBF of the separation structure DB is exposed. After performing the planarizing process, the semiconductor substrate 100 may partially remain between the separation structures DB.

Removing the other part of the semiconductor substrate 100 remaining between the separation structures DB may be performing a cleaning process (for example, silicon full remover SFR) of selectively removing silicon (Si) on the remaining semiconductor substrate 100. The cleaning process (SFR) may be performed until side surfaces of the separation structure DB, a lower surface of the source/drain pattern SD1 or SD2 and a lower surface of the gate insulating layer GI are completely exposed.

The cleaning process (SFR) may be a wet-etching process of selectively etching silicon (Si). For example, only silicon (Si) of the semiconductor substrate 100 may be removed while leaving the device separation layer ST. The cleaning process (SFR) may have a high etch rate for silicon, and the device separation layer ST including silicon oxide may be protected while the cleaning process (SFR) is performed.

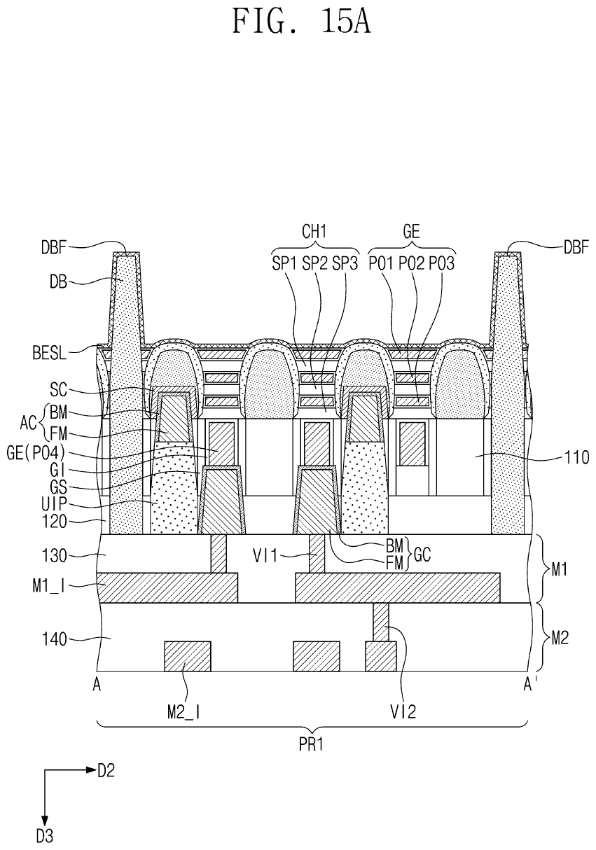

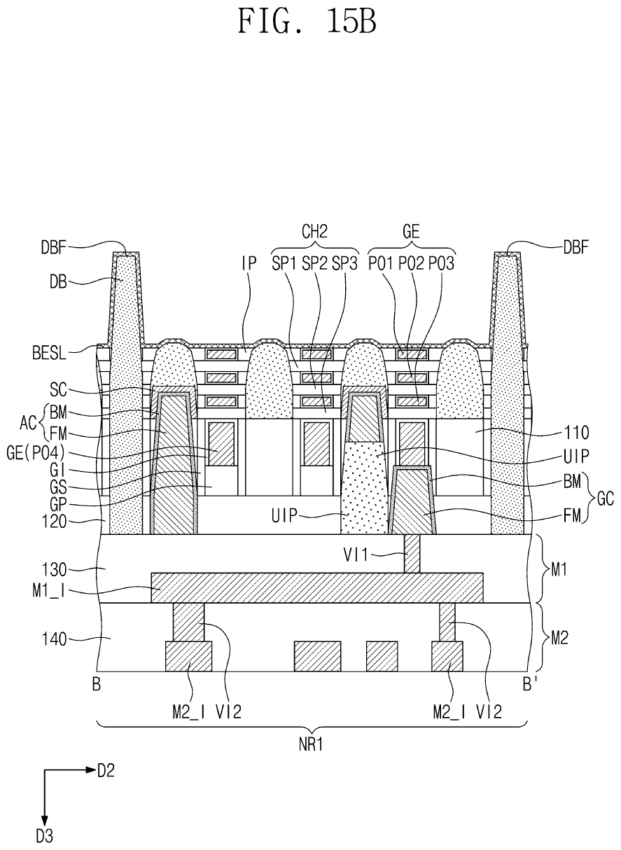

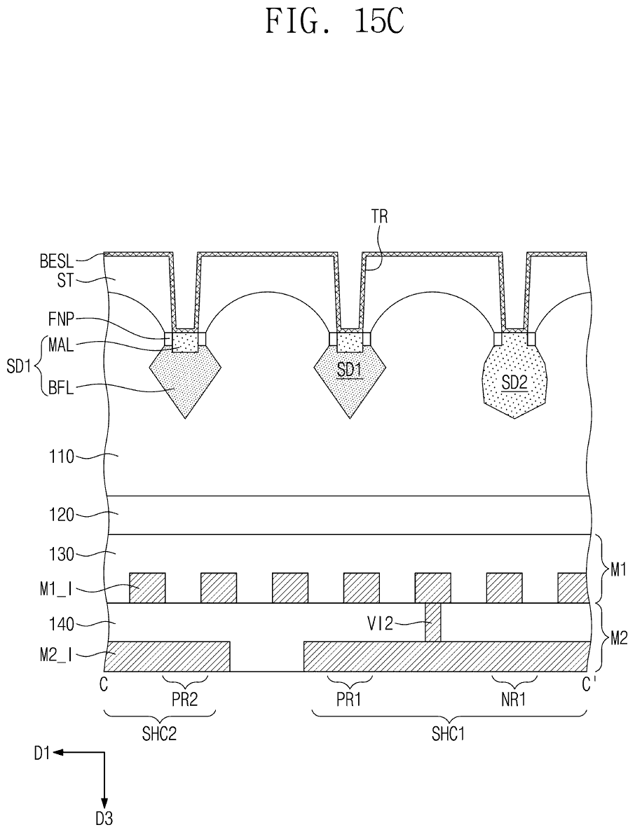

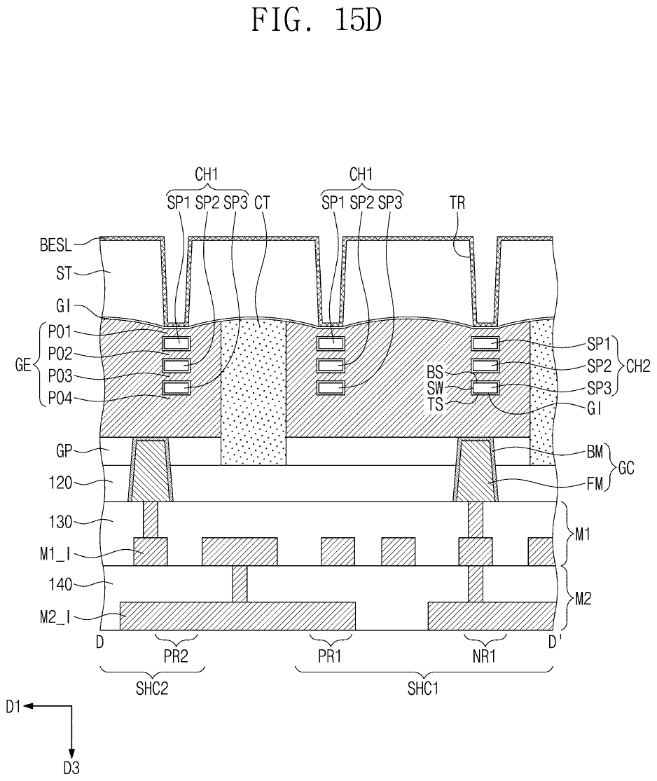

Referring to FIGS. 15A to 15D, the pillar protection pattern BESL may be conformally formed on the lower surface DBF and the side surfaces of the exposed separation structure DB, the lower surface of the source/drain pattern SD1 or SD2 and the lower surface of the gate insulating layer GI. The pillar protection pattern BESL may be formed in a liner shape to have a uniform thickness. The pillar protection pattern BESL may cover the exposed device separation layer ST. For example, the pillar protection pattern BESL may be conformally formed on the trench TR and the device separation layer ST exposed by removing the silicon (Si). The pillar protection pattern BESL may be formed by performing a chemical vapor deposition (CVD) process or atomic layer deposition (ALD) process on the lower surface DBF and the side surfaces of the separation structure DB, the lower surface of the source/drain pattern SD1 or SD2 and the lower surface of the gate insulating layer GI.

The pillar protection pattern BESL may be a single layer or multi-layer. The pillar protection pattern BESL may include an insulating material, and the insulating material may include SiO₂, SiN, SiOC, SiCN, TiO₂ or a combination thereof.

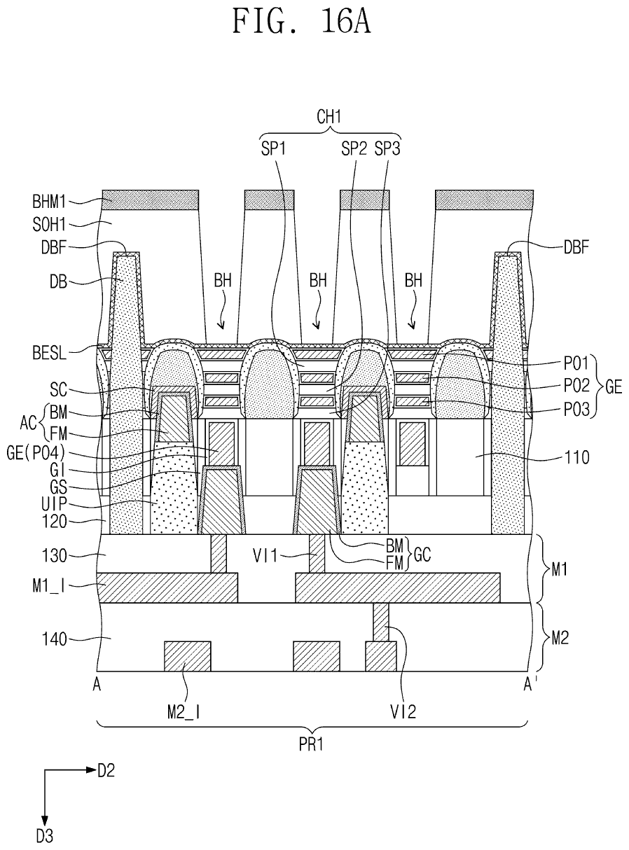

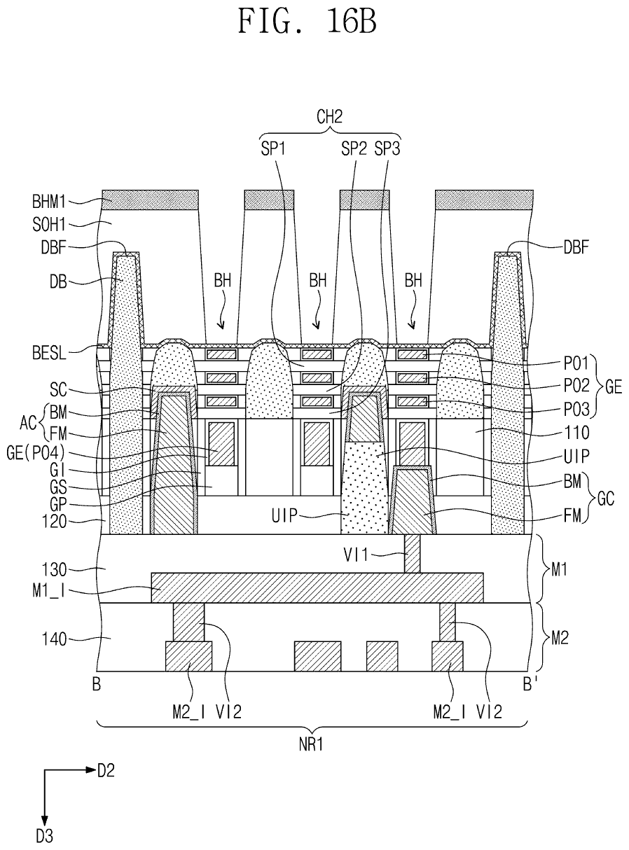

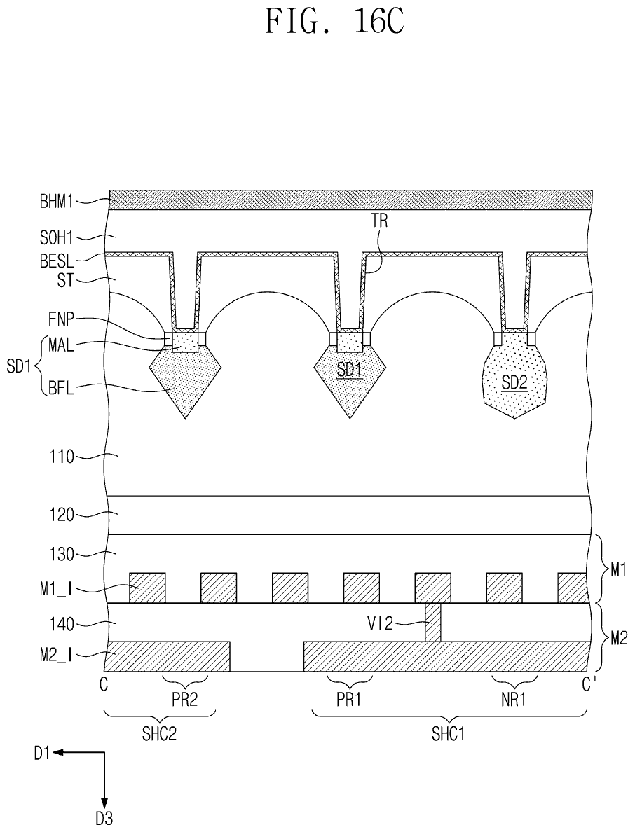

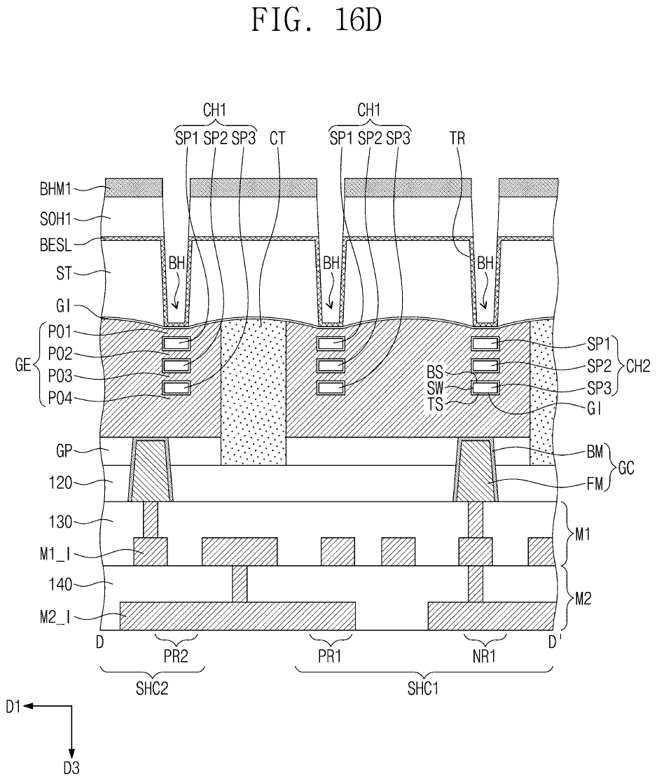

Referring to FIGS. 16A to 16D, a first mold layer SOH1 and a first hardmask layer may be sequentially formed on the pillar protection pattern BESL. The first mold layer SOH1 may include at least one of an amorphous silicon layer, an amorphous carbon layer, a spin-on-hardmask (SOH) layer, and a spin-on-carbon (SOC) layer.

A first hardmask pattern BHM1 may be formed by forming photoresist (PR) on the first hardmask layer, and then performing a photolithography process. Rear surface separation holes BH may be formed by performing an anisotropic etching process or dry etching process on the first mold layer SOH1 using the first hardmask pattern BHM1 as an etching mask. The rear surface separation holes BH may partially expose an upper surface of the pillar protection pattern BESL on the gate insulating layer GI surrounding the first inner electrode PO1.

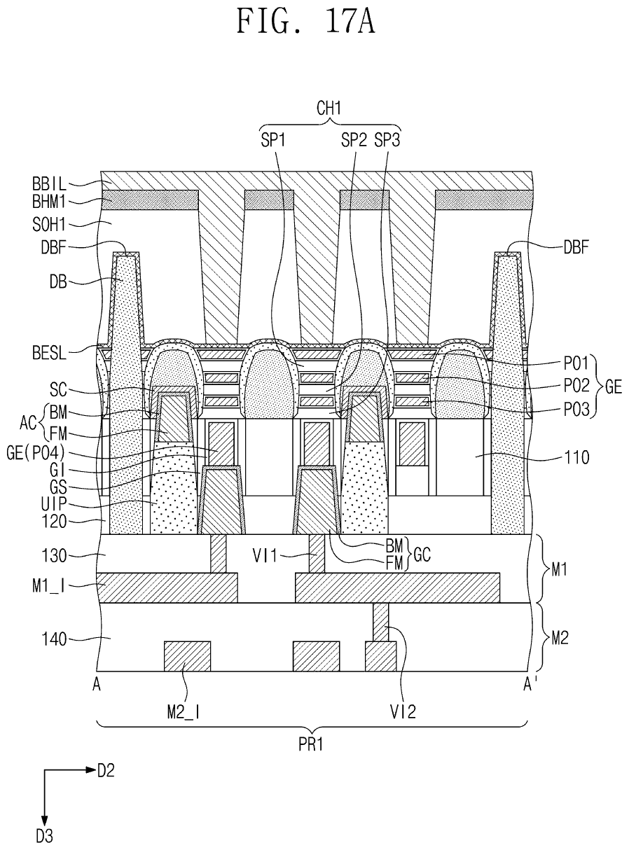

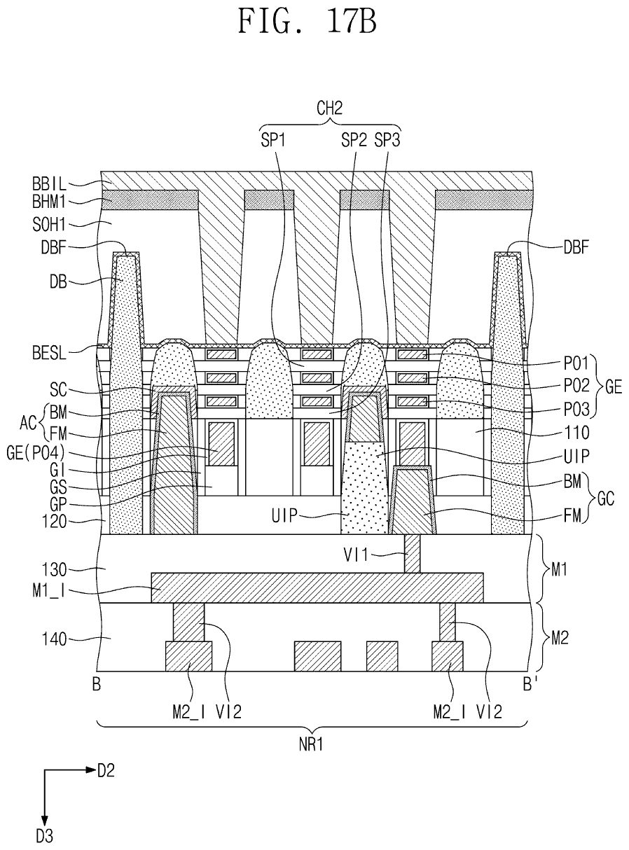

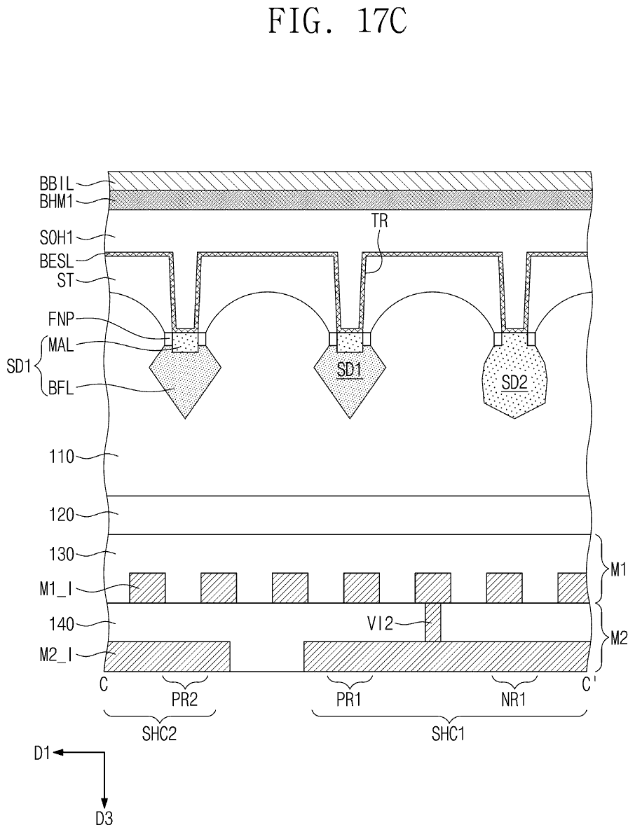

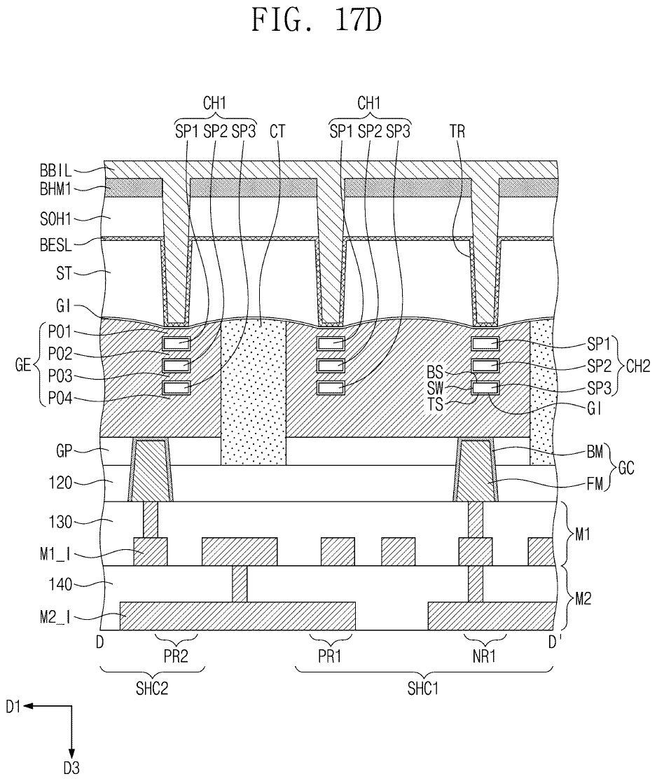

Referring to FIGS. 17A to 17D, a rear surface separation layer BBIL filling insides of the rear surface separation holes BH, and covering the first hardmask pattern BHM1 may be formed. The rear surface separation layer BBIL may be formed by performing a chemical vapor deposition (CVD) process, a physical vapor deposition (PVD) process, or an atomic layer deposition (ALD) process on an upper surface of the pillar protection pattern BESL, a side surface of the first mold layer SOH1, and a side surface and an upper surface of the first hardmask pattern BHM1 exposed by the rear surface separation holes BH.

The rear surface separation layer BBIL may include an insulating material, and the insulating material may include SiO₂, SiN, SiOC, SiCN, TiO₂ or a combination thereof. For example, the rear surface separation layer BBIL may include an insulating material different from the pillar protection pattern BESL. For another example, the rear surface separation layer BBIL may include the same insulating material as the pillar protection pattern BESL.

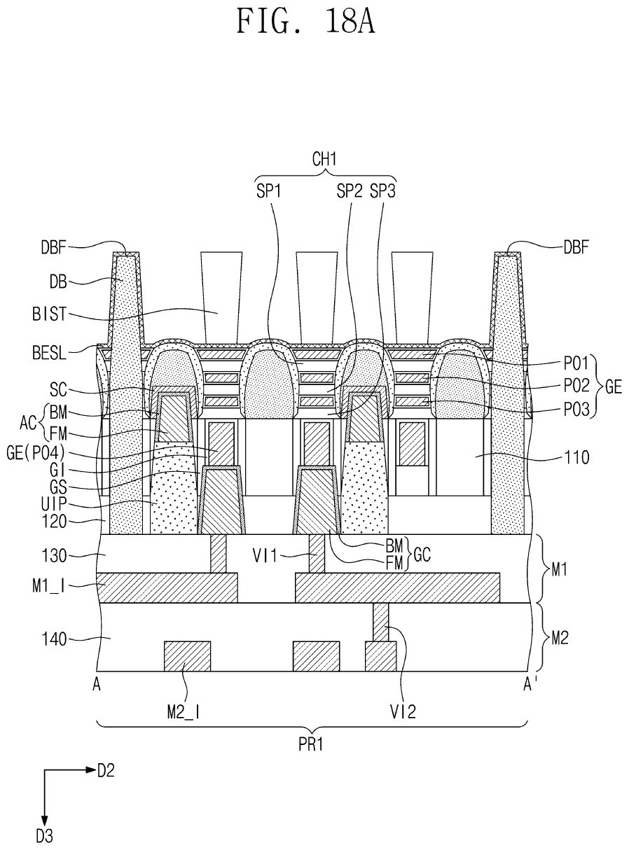

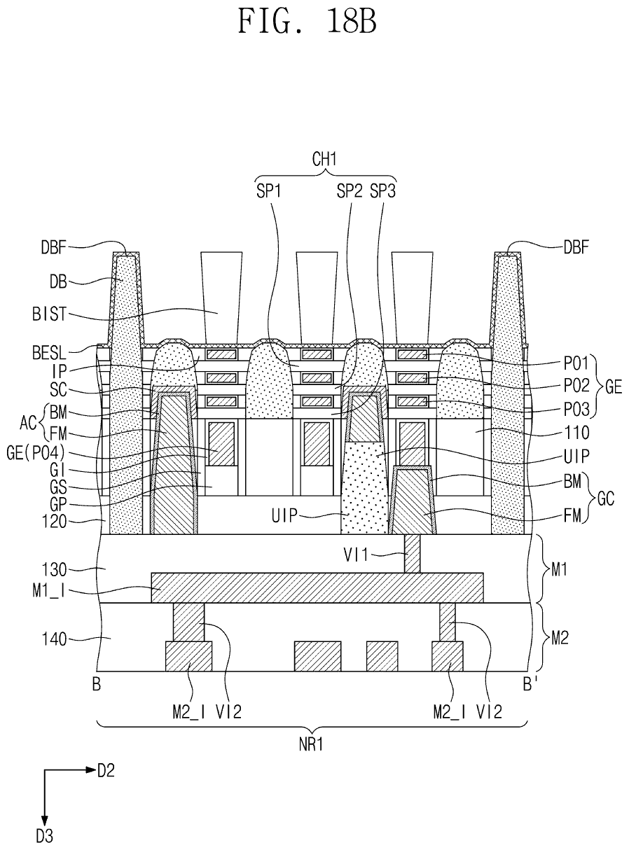

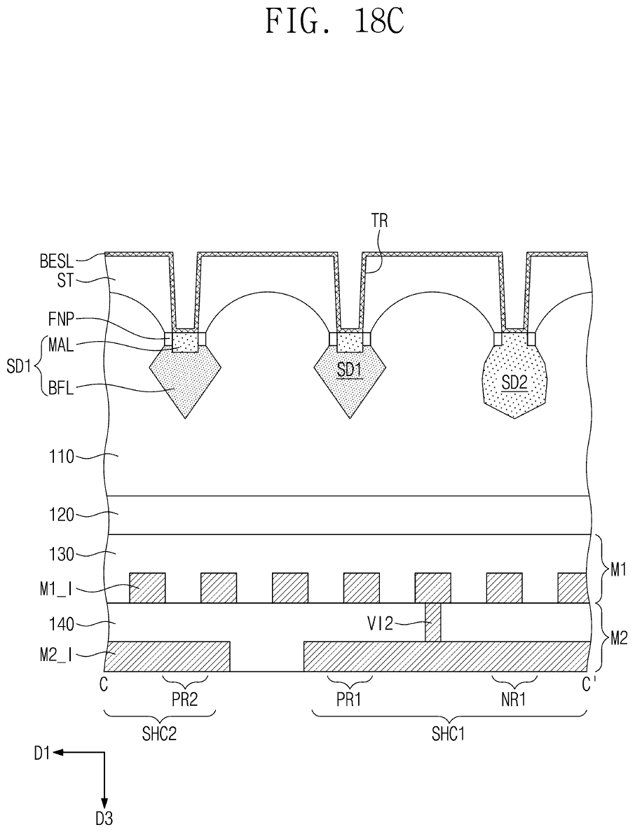

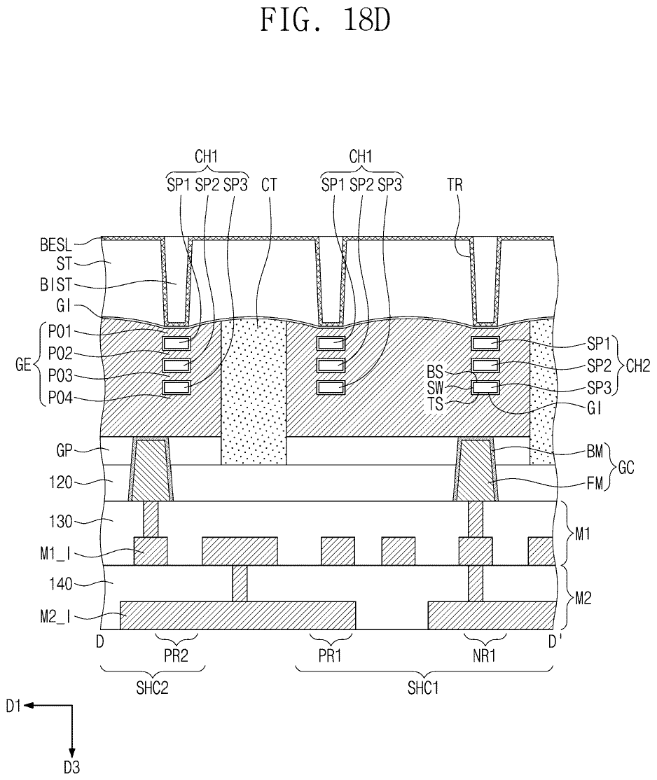

Referring to FIGS. 18A to 18D, the first hardmask pattern BHM1 and the first mold layer SOH1 may be removed so that the rear surface separation layer BBIL may be formed as the rear surface separation pattern BIST. Removing the first hardmask pattern BHM1 and the first mold layer SOH1 may include removing the first hardmask pattern BHM1, and removing the first mold layer SOH1.

Removing the first hardmask pattern BHM1 may be performing the etch-back process on the rear surface separation layer BBIL. A portion of the rear surface separation layer BBIL, the first hardmask pattern BHM1 and a portion of the first mold layer SOH1 may be removed together during performing the etch-back process. The etch-back process may be performed until the pillar protection pattern BESL on the lower surface DBF of the separation structure DB is exposed.

Removing the first mold layer SOH1 may be performing the etch-back process, and then removing the remaining other portion of the first mold layer SOH1. Removing the first mold layer SOH1 may be performing an ashing process or wet-strip process. The remaining rear surface separation layer BBIL may not be removed during the ashing process or wet-strip process due to etching selectivity to be formed as the rear surface separation pattern BIST. The rear surface separation pattern BIST may have a tapered shape in which a width of the upper surface thereof is smaller than a width of the lower surface thereof. The lower surface of the rear surface separation pattern BIST may be substantially coplanar with the lower surface of the pillar protection pattern BESL.

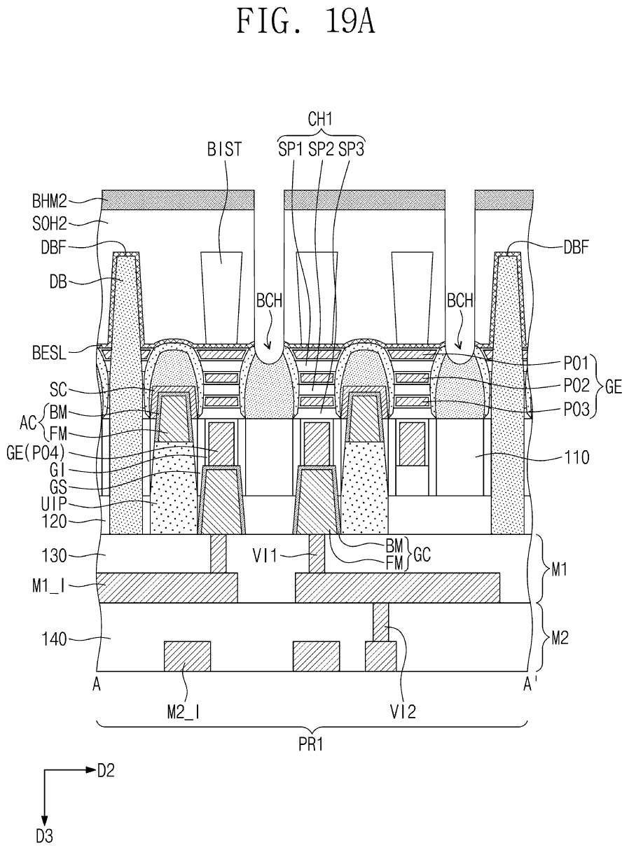

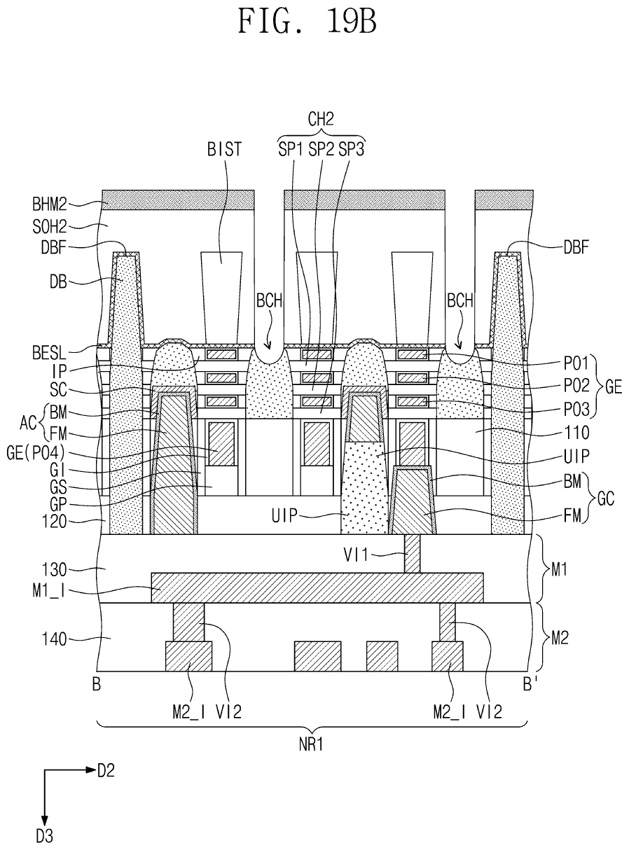

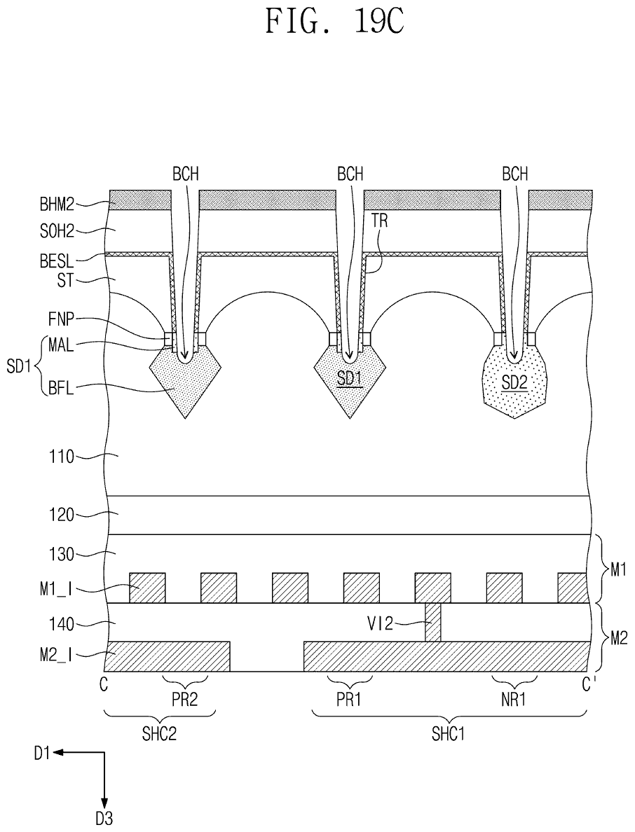

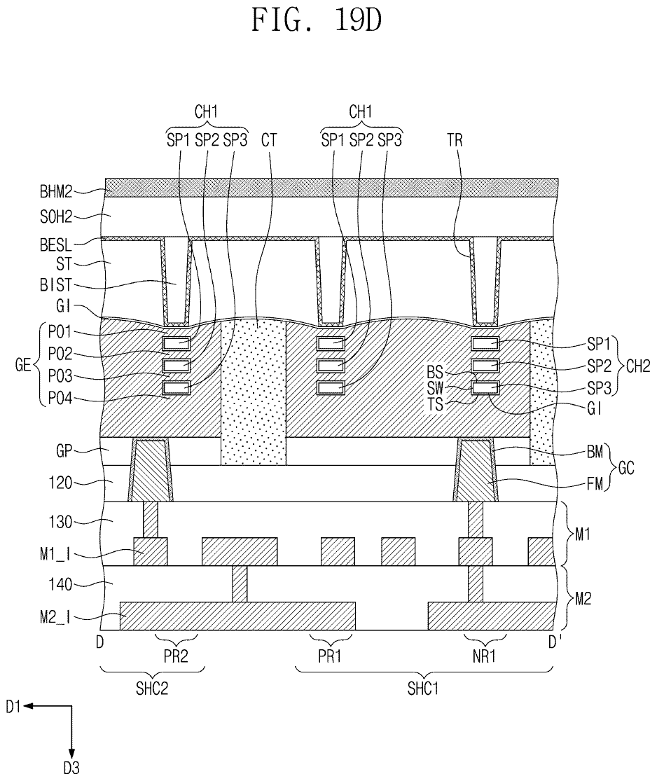

Referring to FIGS. 19A to 19D, a second mold layer SOH2 and a second hardmask layer may be sequentially formed on the pillar protection pattern BESL and the rear surface separation pattern BIST. The second mold layer SOH2 may include at least one of an amorphous silicon layer, an amorphous carbon layer, a spin-on-hardmask (SOH) layer, and a spin-on-carbon (SOC) layer.

A second hardmask pattern BHM2 may be formed by forming photoresist (PR) on the second hardmask layer and then performing a photolithography process. Rear surface contact holes BCH may be formed by performing an anisotropic etching process or dry etching process on the second mold layer SOH2 using the second hardmask pattern BHM2 as an etching mask. The rear surface contact holes BCH may partially expose the lower surface of the source/drain pattern SD1 or SD2. For example, the rear surface contact holes BCH may partially expose the buffer layer BFL and the main layer MAL of the first source/drain pattern SD1.

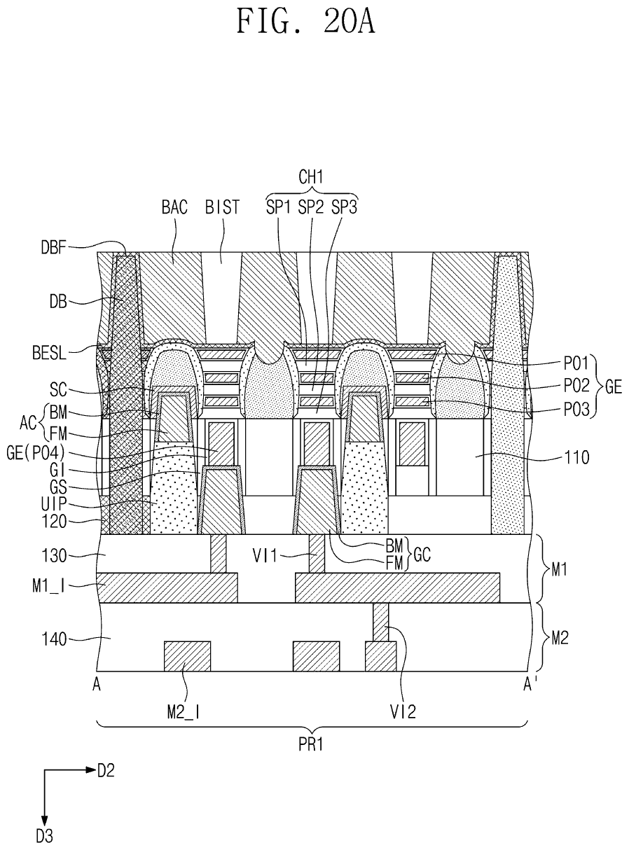

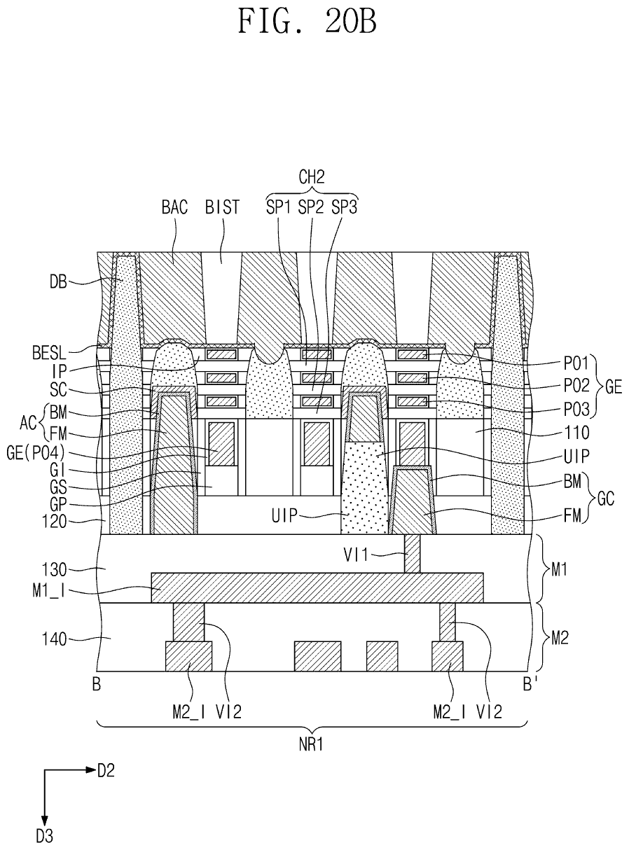

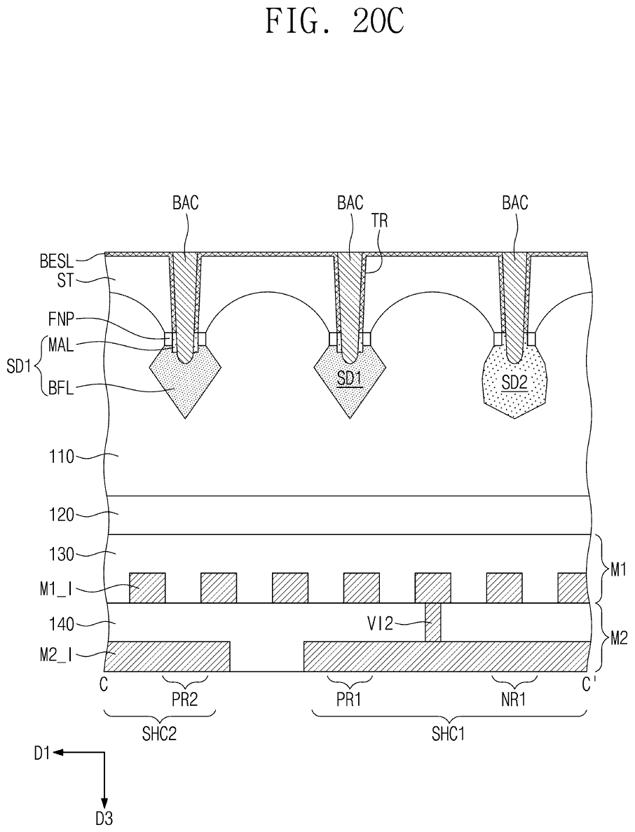

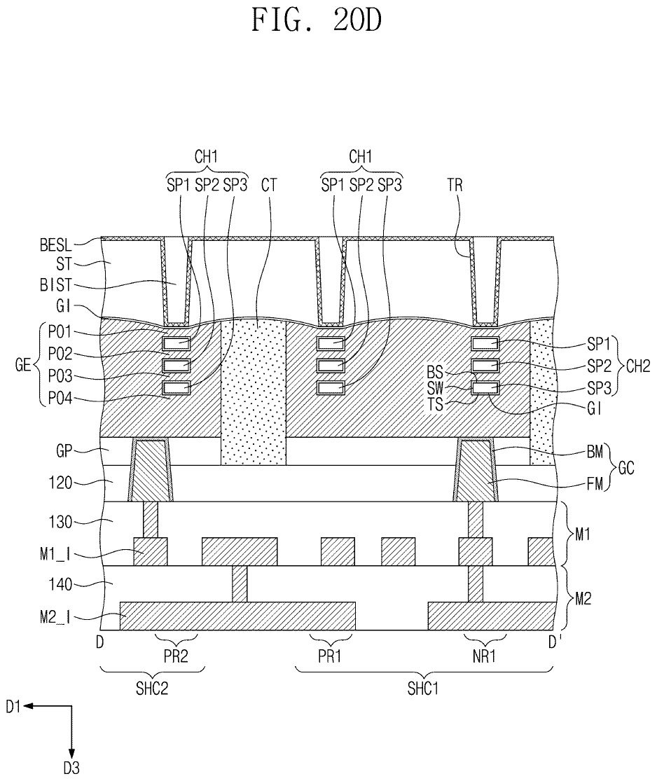

Referring to FIGS. 20A to 20D, the second hardmask pattern BHM2 and the second mold layer SOH2 may be removed. Removing the second hardmask pattern BHM2 may be performing the etch-back process on the second hardmask pattern BHM2. The second mold layer SOH2 may be partially removed during performing the etch-back process. The etch-back process may be performed until the pillar protection pattern BESL on the lower surface DBF of the separation structure DB is exposed.

Removing the second mold layer SOH2 may be performing the etch-back process, and then removing the remaining other portion of the second mold layer SOH2. Removing the second mold layer SOH2 may be performing an ashing process or wet-strip process. The rear surface separation pattern BIST may not be removed during performing the ashing process or wet-strip process due to etching selectivity.

A rear surface barrier pattern may be formed on the pillar protection pattern BESL and the rear surface separation pattern BIST, and a rear surface conductive pattern may be formed on the rear surface barrier pattern. The rear surface barrier pattern and the rear surface conductive pattern may be formed so as to completely cover the pillar protection pattern BESL and the rear surface separation pattern BIST. The rear surface active contact BAC may be formed by performing a planarizing process on the rear surface conductive pattern until a portion of the pillar protection pattern BESL on the lower surface DBF of the separation structures DB and a top surface of the rear surface separation pattern BIST are exposed. The planarizing process may be a chemical mechanical polishing (CMP) process. For example, the rear surface barrier pattern and the rear surface conductive pattern may constitute the rear surface active contact BAC.

Since the pillar protection pattern BESL and the rear surface separation pattern BIST are formed under the gate electrode GE, leakage current occurring between the source/drain pattern SD1 or SD2 and the rear surface active contact BAC corresponding to another source/drain pattern SD1 or SD2 may be prevented. Since a width of the rear surface separation pattern BIST is targeted and optimized, a volume of the rear surface active contact BAC occupying in the semiconductor device may increase. For example, since a volume of the rear surface active contact BAC electrically connected to the source/drain pattern SD1 or SD2 increases, total resistance of a rear surface wire may be reduced. Accordingly, electrical characteristics of the semiconductor device manufactured according to the manufacturing method according to the inventive concept may be improved.

The lower power wires VPR1, VPR2, and VPR3 may be formed on the rear surface active contact BAC and the rear surface separation pattern BIST. The lower power wires VPR1, VPR2, and VPR3 may be connected to at least one of the rear surface active contacts BAC. The power transmission network layer PDN may be formed on the lower power wires VPR1, VPR2, and VPR3. The power transmission network layer PDN may be formed so as to apply the source voltage and the drain voltage to the lower power wires VPR1, VPR2, and VPR3.

In a three-dimensional field effect transistor according to the inventive concept, since a pillar protection pattern is formed under a gate electrode before forming a rear surface active contact and a rear surface separation pattern, a high-dielectric layer of a gate insulating layer may be prevented from being damaged. For example, loss or damage of the high-dielectric layer occurring in an etching process of forming the rear surface separation pattern may be prevented. Accordingly, reliability of a semiconductor device according to the inventive concept may be improved.

In addition, since the pillar protection pattern is formed under the gate electrode, leakage current occurring between a source/drain pattern and the rear surface active contact may be prevented.

Since a width of the rear surface separation pattern is optimized in a process of forming the pillar protection pattern and then forming the rear surface separation pattern, a volume occupied by the rear surface active contact may increase. For example, since a volume of the rear surface active contact electrically connected to the source/drain pattern increases, total resistance of the rear surface wire may be reduced. Accordingly, electrical characteristics of the semiconductor device according to the inventive concept may be improved.

While the inventive concept has been particularly shown and described with reference to embodiments thereof, it will be understood that various changes in form and details may be made therein without departing from the spirit and scope of the present invention as set forth in the following claims.

What is claimed is:

1. A semiconductor device comprising:
a substrate;
a lower power wire provided in a lower portion of the substrate;
a rear surface active contact on the lower power wire;
a rear surface separation pattern separating the rear surface active contact on the lower power wire;
a channel pattern on the rear surface separation pattern, the channel pattern including a plurality of semiconductor patterns stacked spaced apart from each other;
a source/drain pattern connected to the channel pattern;
a gate electrode between the rear surface separation pattern and one of the plurality of semiconductor patterns and between each of the plurality of semiconductor patterns; and
a pillar protection pattern interposed between the gate electrode and the rear surface separation pattern,
wherein the pillar protection pattern and the rear surface separation pattern include different insulating materials respectively.

2. The semiconductor device of claim 1, wherein the insulating materials formed of the pillar protection pattern and the rear surface separation pattern include SiO₂, SiN, SiOC, SiCN, TiO₂, or a combination thereof.

3. The semiconductor device of claim 1, wherein the pillar protection pattern includes at least one of SiO₂, SiN, SiOC, and SiCN, and
wherein the rear surface separation pattern includes one of SiO₂, SiN, SiOC, and SiCN, different from the pillar protection pattern.

4. The semiconductor device of claim 1, further comprising:
a gate insulating layer on the gate electrode,
wherein the pillar protection pattern is interposed between the gate insulating layer and the rear surface separation pattern.

5. The semiconductor device of claim 1, wherein the plurality of semiconductor patterns includes a first semiconductor pattern, a second semiconductor pattern, and a third semiconductor pattern sequentially stacked, and
wherein the gate electrode comprises:
a first inner electrode having a first width in a first direction parallel to an upper surface of the substrate between the rear surface separation pattern and the first semiconductor pattern in a second direction perpendicular to the upper surface of the substrate;
a second inner electrode having a second width in the first direction between the first semiconductor pattern and the second semiconductor pattern in the second direction;
a third inner electrode having a third width in the first direction between the second semiconductor pattern and the third semiconductor pattern in the second direction; and
an outer electrode having a fourth width in the first direction on the third semiconductor pattern,
wherein the first width is greater than each of the second to fourth widths.

6. The semiconductor device of claim 5, wherein an upper surface of the rear surface separation pattern has a fifth width in the first direction, and a lower surface of the rear surface separation pattern has a sixth width in the first direction, and
wherein the fifth width is smaller than the sixth width.

7. The semiconductor device of claim 6, wherein the rear surface separation pattern has a tapered shape in which a width thereof becomes smaller toward the second direction.

8. The semiconductor device of claim 6, wherein the fifth width and the sixth width are smaller than each of the first to third widths.

9. The semiconductor device of claim 6, wherein the fifth width or the sixth width is equal to or smaller than the fourth width.

10. The semiconductor device of claim 6, wherein the fifth width is smaller than the fourth width, and
wherein the sixth width is greater than the fourth width.

11. The semiconductor device of claim 1, wherein the rear surface active contact penetrates the substrate to electrically connect the lower power wire to the source/drain pattern, and
wherein the uppermost surface of the rear surface active contact is located at a higher level than the uppermost surface of the pillar protection pattern.

12. The semiconductor device of claim 1, wherein the lowermost surface of the rear surface active contact is located at the same level as the lowermost surface of the rear surface separation pattern.

13. The semiconductor device of claim 1, wherein the rear surface active contact includes a rear surface conductive pattern and a rear surface barrier pattern surrounding the rear surface conductive pattern.

14. A semiconductor device comprising:
a substrate including a rear surface separation pattern;
a lower power wire buried in a lower portion of the substrate;
a channel pattern on the substrate, the channel pattern including a plurality of semiconductor patterns stacked spaced apart from each other;
source/drain patterns connected to the channel pattern;
a gate electrode between the rear surface separation pattern and one of the plurality of semiconductor patterns and between each of the plurality of semiconductor patterns;
a rear surface active contact electrically connecting the lower power wire and one of the source/drain patterns, and including a body portion and a protrusion portion on the body portion;
an upper active contact electrically connecting the other one of the source/drain patterns; and
a pillar protection pattern interposed between the gate electrode and the rear surface separation pattern,
wherein the pillar protection pattern extends onto a lower surface of the other one of the source/drain patterns, and
wherein the protrusion portion of the rear surface active contact penetrates the pillar protection pattern.

15. The semiconductor device of claim 14, wherein the gate electrode includes a first inner electrode, a second inner electrode, a third inner electrode and an outer electrode,
wherein the rear surface separation pattern has the maximum width less than a width of each of the first to third inner electrodes, and
wherein the widths of the first to third inner electrodes and the rear surface separation pattern are defined in a direction parallel to an upper surface of the substrate.

16. The semiconductor device of claim 14, wherein the pillar protection pattern and the rear surface separation pattern include the same insulating material.

17. The semiconductor device of claim 14, wherein the pillar protection pattern and the rear surface separation pattern are integrally formed.

18. A semiconductor device comprising:
a substrate including a rear surface separation pattern;
a device separation layer provided on the substrate to define the rear surface separation pattern;
a channel pattern on the rear surface separation pattern, the channel pattern including a plurality of semiconductor patterns stacked spaced apart from each other, and the plurality of semiconductor patterns including a first semiconductor pattern, a second semiconductor pattern and a third semiconductor pattern;
source/drain patterns connected to the channel pattern;
a gate electrode between the plurality of semiconductor patterns, the gate electrode including a first inner electrode, a second inner electrode, and a third inner electrode interposed between adjacent semiconductor patterns among the plurality of semiconductor patterns, and an outer electrode on the third semiconductor pattern;
a gate insulating layer interposed between the gate electrode and the channel pattern;
a gate spacer on a sidewall of the gate electrode;
a gate capping pattern on an upper surface of the gate electrode;
an interlayered insulating layer covering the source/drain patterns and the gate capping pattern;
an upper active contact penetrating the interlayered insulating layer to be electrically connected to a first source/drain pattern of the source/drain patterns;
a metal-semiconductor compound layer interposed between the upper active contact and the first source/drain pattern;
a gate contact penetrating the interlayered insulating layer and the gate capping pattern to be electrically connected to the gate electrode;
a first metal layer on the interlayered insulating layer, the first metal layer including a first wire electrically connected to the gate contact;
a second metal layer on the first metal layer, the second metal layer including a second wire electrically connected to the first metal layer;
a lower power wire provided in a lower portion of the substrate;
a rear surface active contact penetrating the substrate to electrically connect the lower power wire to a second source/drain pattern of the source/drain patterns; and
a pillar protection pattern interposed between the rear surface separation pattern and the gate insulating layer on the first inner electrode,
wherein the uppermost surface of the rear surface active contact is located at a higher level than an upper surface of the pillar protection pattern and an upper surface of the rear surface separation pattern, and
the pillar protection pattern and the rear surface separation pattern respectively include different insulating materials.

19. The semiconductor device of claim 18, wherein the pillar protection pattern includes at least one of SiO₂, SiN, SiOC, and SiCN, and
wherein the rear surface separation pattern includes one of SiO₂, SiN, SiOC, and SiCN, different from the pillar protection pattern.

20. The semiconductor device of claim 18, wherein the rear surface separation pattern has the maximum width less than a width of each of the first to third inner electrodes, and
wherein the widths of the first to third inner electrodes and the rear surface separation pattern are defined in a direction parallel to an upper surface of the substrate.
